(19) United States
(12) Patent Application Publication
(10) Pub. No.: US 2008/0258133 A1
(43) Pub. Date: Oct. 23, 2008

(54) Semiconductor Device and Method of Fabricating the Same

(75) Inventor: Tae-Yeon Seong, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/092,017

(22) PCT Filed: Oct. 27, 2006
(86) PCT No.: PCT/KR2006/004425

§ 371 Date: Apr. 29, 2008

(30) Foreign Application Priority Data
Oct. 29, 2005 (KR) 10-2005-0102645
Nov. 14, 2005 (KR) 10-2005-0108408
Dec. 27, 2005 (KR) 10-2005-0130217

(51) Int. Cl. H01L 31/20; H01L 29/12

(52) U.S. Cl. 257/14; 438/483; 257/E29.069

(57) ABSTRACT

Disclosed is a semiconductor device. The semiconductor device includes a first type nitride-based cladding layer formed on a growth substrate having an insulating property, a multi quantum well nitride-based active layer formed on the first type nitride-based cladding layer and a second type nitride-based cladding layer, which is different from the first type nitride-based cladding layer and is formed on the multi quantum well nitride-based active layer. A tunnel junction layer is formed between the undoped buffering nitride-based layer and the first type nitride-based cladding layer or/and formed on the second type nitride-based cladding layer.

### TECHNICAL FIELD

The present invention relates to a semiconductor device. More particularly, the present invention relates to a semiconductor device having high brightness and a method of fabricating the same.

### BACKGROUND ART

Nitride-based semiconductors are mainly used for optical semiconductor devices, such as light emitting diodes or laser diodes. III-nitride-based semiconductors are direct-type compound semiconductor materials having widest band gaps used in optical semiconductor fields. Such III-nitride-based semiconductors are used to fabricate high efficient light emitting devices capable of emitting light having wide wavelength bands in a range between a yellow band and an ultraviolet band. However, although various endeavors have performed for several years in various industrial fields to provide the light emitting device having the large area, high capacity, and high brightness, such endeavors have ended in a failure due to the following basic difficulties related to materials and technologies.

First, a difficulty of providing a substrate adapted to grow a nitride-based semiconductor having a high quality.

Second, a difficulty of growing an InGaN layer and an AlGaN layer including a great amount of indium (In) or aluminum (Al).

Third, a difficulty of growing a p-nitride-based semiconductor having a higher hole carrier density.

Fourth, a difficulty of forming a high-quality ohmic contact electrode (=ohmic contact layer) suitable for an n-nitride-based semiconductor and a p-nitride-based semiconductor.

Nevertheless of the above difficulties derived from materials and technologies, in late 1993, Nichia chemicals (Japanese Company) has developed a blue light emitting device by using a nitride-based semiconductor for the first time in the world. In these days, a white light emitting device including a high brightness blue/green light emitting device coupled with a phosphor has been developed. Such a white light emitting device is practically used in various illumination industrial fields.

In order to realize a next-generation light emitting device having high efficiency, large area and high capacity, such as a light emitting diode (LED) or a laser diode (LD) employing a high-quality nitride-based semiconductor, a low EQE (extraction quantum efficiency) and heat dissipation must be improved.

Nitride-based LEDs are classified into two types based on the shape of a light emitting device and the emission direction of light generated from a nitride-based active layer. The shape of the light emitting device relates to the electric characteristics of a substrate. Thus, in accordance with the shape of the light emitting device, the nitride-based LEDs are classified into a MESA-structured nitride-based LED, in which a nitride-based light emitting structure is grown on an upper portion of an insulating substrate and N type and P type ohmic electrode layers are aligned in parallel to the nitride-based light emitting structure, and a vertical-structured nitride-based LED which is grown on an upper portion of a conductive substrate including silicon (Si) or silicon carbide (SiC).

In view of light intensity, heat elimination, and device reliability, the vertical-structured nitride-based LED is advantageous than the MESA-structured nitride-based LED because the vertical-structured nitride-based LED is grown on the conductive substrate having superior electric and thermal properties. In addition, the nitride-based LEDs are classified into a top-emission type LED and a flip-chip type LED according to the emission direction of light generated from an active layer of a nitride-based light emitting device. In the case of the top-emission type LED, the light generated from the nitride-based active layer is emitted to an exterior through a p-ohmic contact layer. In contrast, in the case of the flip-chip type LED, light generated from the nitride-based light emitting structure using a high-reflective p-ohmic contact layer is emitted to an exterior through a transparent (sapphire) substrate.

In the case of the MESA-structured nitride-based LED, which has been widely used, light generated from the nitride-based active layer is emitted to an exterior through a p-ohmic electrode layer that directly makes contact with a p-nitride-based cladding layer. Therefore, a high-quality p-ohmic contact layer is necessary in order to obtain the top-emission type MESA-structured nitride-based LED having a high quality. Such a high-quality p-ohmic contact layer must have a higher light transmittance of 90% or more, and a specific contact ohmic resistance value as low as possible.

In other words, in order to fabricate a next-generation nitride-based top emission type LED having the high capacity, large area, and high brightness, electric characteristics, such as low specific contact ohmic resistance and sheet resistance, are essentially necessary to simultaneously perform the current spreading in the lateral direction and the current injecting in the vertical direction of the p-electrode layer such that a high sheet-resistance value of a p-nitride-based cladding layer caused by a low hole density can be compensated. In addition, a p-ohmic contact electrode having higher light transmittance and sheet-resistance must be provided in order to minimize light absorption when the light generated from the nitride-based active layer is output to the exterior through the p-type ohmic electrode layer.

The MESA-structured top-emission type LED employing the nitride-based semiconductor, which is generally known in the art, uses a p-ohmic electrode layer that can be obtained by stacking a dual layer of thin nickel (Ni) gold (Au) or a thick transparent conducting layer, such as indium tin oxide (ITO), on a p-nitride-based cladding layer and then annealing the p-nitride-based cladding layer in the oxygen (O₂) atmosphere or in the nitrogen (N₂) atmosphere. In particular, when the ohmic electrode layer including semi-transparent nickel-gold (Ni—Au) and having a low specific contact resistance value of about 10⁻³ cm² to 10⁻⁴ cm² is subject to the annealing process at the temperature of about 500° C., nickel oxide (NiO), which is p-semiconductor oxide, is distributed in the form of an island on the interfacial surface between the p-nitride-based cladding layer and the nickel-gold ohmic electrode layer. In addition, gold (Au) particles having superior conductivity are embedded into the island-shaped nickel oxide (NiO), thereby forming a micro structure.

Such a micro structure may reduce the height and width of the schottky barrier formed between the p-nitride-based cladding layer and the nickel-gold ohmic electrode layer, provide hole carriers to the n-nitride-based cladding layer, and distribute gold (Au) having superior conductivity, thereby achieving superior current spreading performance. However, since the nitride-based top emission type LED employing the p-ohmic electrode layer consisting of nickel-gold (Ni—Au) includes gold (Au) that reduces the light transmittance, the nitride-based top emission type LED represents a low EQE (external quantum efficiency), so the nitride-based top emission type LED is not suitable for the next-generation LED having the high capacity, large area and high brightness.

For this reason, another method of providing a p-ohmic contact layer without using the semi-transparent Ni—Au layer has been suggested. According to this method, the p-ohmic contact layer is obtained by directly depositing a transparent conducting oxide layer including a thick transparent conducting material, such as indium (In), tin (Sn) or zinc (Zn) which is generally known in the art as a material for a high transparent ohmic contact electrode, and a transparent conducting nitride layer including transition metal, such as titanium (Ti) or tantalum (Ta), on a p-nitride-based cladding layer. However, although the p-ohmic electrode layer fabricated through the above method can improve the light transmittance, the interfacial characteristic between the p-ohmic electrode layer and the p-nitride-based cladding layer is deteriorated, so the p-ohmic electrode layer is not suitable for the MESA-structured top emission type nitride-based LED.

Various documents (for example, IEEE PTL, Y. C. Lin, etc. Vol. 14, 1668 and IEEE PTL, Shyi-Ming Pan, etc. Vol. 15, 646) disclose a nitride-based top emission type LED having superior electrical and thermal stability and representing the great EQE by employing a p-ohmic electrode layer, which is obtained by combining a transparent conducting oxide layer having superior electrical conductivity with a metal, such as nickel (Ni) or ruthenium (Ru), without using a noble metal, such as gold (Au) or a platinum (Pt) in such a manner that the p-ohmic electrode layer has light transmittance higher than that of the conventional p-ohmic electrode layer of a nickel-gold (Ni—Au) electrode.

Recently, Semicond. Sci. Technol. discloses a document related to a nitride-based top emission type LED, which employs an indium tin oxide (ITO) transparent layer as a p-ohmic electrode layer and represents an output power higher than that of a conventional LED employing the conventional nickel-gold (Ni—Au) ohmic electrode.

However, although the p-ohmic electrode layer employing the ITO transparent layer can maximize the EQE of the LED, a great amount of heat may be generated when the nitride-based LED is operated because the p-ohmic electrode layer has a relatively high specific contact ohmic resistance value, so the above p-ohmic electrode layer is not suitable for the nitride-based LED having the large area, high capacity, and high brightness.

In order to improve the electrical characteristics of the LED, which may be degraded due to the p-ohmic electrode layer including transparent conductive oxide (TCO) or transparent conductive nitride (TCN), LumiLeds Lighting Company (U.S.) has developed an LED having higher light transmittance and superior electrical characteristics by combining indium tin oxide (ITO) with thin nickel-gold (Ni—Au) or thin nickel-silver (Ni—Ag) (U.S. Pat. No. 6,287,947 issued to Michael J. Ludowise etc.). However, the LED disclosed in the above patent requires a complicated process to form a p-ohmic contact layer and employs gold (Au) or silver (Ag), so this LED is not suitable for the nitride-based LED having the high capacity, large area and high brightness.

Recently, a new MESA-structured nitride-based top emission type LED provided with a high-quality p-ohmic electrode layer has been developed by Samsung Electronics. According to the above MESA-structured nitride-based top emission type LED, new spherical transparent nano particles having sizes of 100 nano meter or less are provided onto an interfacial surface between a p-nitride-based cladding layer and a transparent conducing oxide electrode, such as an ITO electrode or a ZnO electrode, so as to reduce the high ohmic contact resistance value therebetween.

In addition, various patent documents and publications disclose technologies related to the fabrication of the MESA-structured top-emission type nitride-based LED. For instance, in order to directly use a highly transparent conducting layer (ITO layer or TiN layer) as a p-ohmic electrode layer, the transparent conducting layer (ITO layer or TiN layer) is deposited onto a super lattice structure including +-InGaN/n-GaN, n+-GaN/n-InGaN, or n+-InGaN/n-InGaN after repeatedly growing the super lattice structure on an upper surface of a p-nitride-based cladding layer. Then, a high-quality n-ohmic contact is formed through an annealing process, and a tunneling junction process is performed, thereby obtaining the MESA-structured top-emission type nitride-based LED having the high quality.

In these days, many companies recognize that the MESA-structured top-emission type nitride-based LED including the transparent p-ohmic electrode layer combined with a nitride-based light emitting structure grown on a sapphire substrate may not be suitable for the next-generation LED having the high capacity, large area and high brightness because of great amount of heat generated from an active layer and various interfacial layers during the operation of a light emitting device.

LumiLeds Lighting Company (U.S.) and Toyoda Gosei Company (JP) have developed another advanced nitride-based light emitting device for a next-generation light source having high brightness by stacking a nitride-based light emitting structure on a sapphire substrate having an insulating property. According to the above nitride-based light emitting device, silver (Ag) and rhodium (Rh) materials, which are high-reflective thin metals, are combined with the p-ohmic electrode layer to provide the MESA-structured nitride-based flip-chip LED, which is an LED chip having the high capacity and the large area of 1 square millimeter scale. However, such a MESA-structured nitride-based flip-chip LED may degrade the product yield due to complicated processes. In addition, since the p-ohmic electrode layer including the high-reflective thin metals (Ag and Rh) is thermally unstable and represents low light reflectance at a wavelength band of 400 nm or less, so the p-ohmic electrode layer is not suitable for a (near) ultraviolet light emitting diode that emits light having a short wavelength.

Recently, the vertical-structured nitride-based LED has been spotlighted as a next-generation white light source having the large area, high brightness and high capacity. The vertical-structured nitride-based LED can be obtained by stacking a nitride-based light emitting structure on the conductive silicon carbide (SiC) substrate representing electrical and thermal stability, or can be obtained through the steps of stacking a nitride-based light emitting structure on the sapphire substrate having insulating properties, removing the sapphire substrate through a laser lift-off (LLO) scheme using a strong laser beam, and bonding the structure onto a heat sink having the superior heat emission function and including high-reflective ohmic electrode materials, such as Ag or Rh, copper (Cu) or a copper-related alloy. Since the above vertical-structured nitride-based LED employs the heat sink having superior thermal conductivity, the vertical-structured nitride-based LED can easily emit heat during the operation of the LED having the large area and high capacity.

However, the above vertical-structured nitride-based LED requires a p-type high reflective ohmic electrode layer having thermal stability and represents total internal reflection/absorption of light, thereby causing the low EQE and low product yield and resulting in low productivity and high costs. Thus, the vertical-structured nitride-based LED must be more advanced so as to be used as a next generation white light source having high-brightness. In particular, although the light emitting device stacked on the silicon carbide (SiC) substrate represents superior heat dissipation, there are technical difficulties and high costs in fabrication of the SiC substrate. In addition, Since the vertical-structured nitride-based LED exhibits the low EQE due to the high light absorption, the nitride-based LED employing the SiC substrate may not be extensively used.

The vertical-structured nitride-based LED employing the LLO scheme, which is recently spotlighted as a next generation white light source having high brightness, is classified into a p-side down vertical-structured nitride-based LED and an n-side down vertical-structured nitride-based LED according to the emission direction of light generated from the active layer.

In general, the p-side down vertical-structured nitride-based LED, which emits light through an n-nitride-based cladding layer, represents superior optical and electrical properties and is simply manufactured as compared with the n-side vertical-structured nitride-based LED, which emits light generated from the active layer through a p-nitride-based cladding layer.

The difference of optical and electrical properties between the p-side down vertical-structured nitride-based LED and the n-side down vertical-structured nitride-based LED is caused by the characteristic difference of reflective and transparent ohmic electrode layers used to manufacture the p-side down vertical-structured nitride-based LED and the n-side down vertical-structured nitride-based LED. In the case of the p-side down vertical-structured nitride-based LED, as disclosed in various documents, the p-ohmic electrode layer includes high reflective metals, such as silver (Ag) or rhodium (Rh), and the n-nitride-based cladding layer having low sheet resistance is positioned at the uppermost portion of the p-side down vertical-structured nitride-based LED, so the p-side down vertical-structured nitride-based LED can directly emit light to the exterior through the n-nitride-based cladding layer without using an additional high transparent n-ohmic electrode layer. Accordingly, the p-side down vertical-structured nitride-based LED has superior LED characteristics.

However, as mentioned above, the p-side down vertical-structured nitride-based LED may significantly degrade various characteristics because the high reflective p-ohmic electrode layer causes a problem in the light emitting structure that emits light having a wavelength band of 400 nm or less. Different from the p-side down vertical-structured nitride-based LED, the n-side down vertical-structured nitride-based LED can use the high reflective metals, such as silver (Ag) or rhodium (Rh), as materials for the n type high reflective ohmic electrode layer. In addition, aluminum (Al) having superior reflectance can be used as a material for the n type high reflective ohmic electrode layer in a short wavelength band of 400 nm or less. However, since the p-nitride-based cladding layer having high sheet resistance is positioned at the uppermost portion of the n-side down vertical-structured nitride-based LED, the high transparent conductive p-ohmic electrode layer is additionally required. However, as described above, there is difficulty in fabrication of the high transparent conductive p-ohmic electrode layer due to bad electric characteristics of the p-nitride-based cladding layer.

Various companies in the world famous for the nitride-based light emitting devices, such as OSRAM in Germany, sell the LED having the large area, high capacity and high brightness by fabricating the LED using the LLO technique. However, when the nitride-based LED having the large area, high capacity and high brightness is fabricated by using the LLO technique, the product yield of the nitride-based LED is about 50% or less, so low productivity and high costs may result.

In order to realize the semiconductor devices, that is, in order to provide optical devices using GaN-based semiconductors, such as RF transistors having high capacity and being used in the extremely low or high temperature condition, various electronic devices, LEDs, LDs, photo-detectors, or solar cells, a substrate capable of growing an epitaxial stack structure including GaN-based semiconductors having high quality must be fabricated.

In order to obtain such a substrate, materials having similar lattice constant and thermal expansion coefficient must be selected. To this end, preparation of a homo-substrate, that is, preparation of a growth substrate including III-nitride-based material is necessarily required.

Conventionally, in order to grow the GaN-based semiconductor epitaxial stack structure suitable for high-performance electronic and optoelectronic devices, hetero-substrates including sapphire, silicon carbide, silicon or gallium arsenide have been developed and used.

Among other things, sapphire (Al₂O₃) and silicon carbide (SiC) substrates have recently been used extensively to grow the GaN-based semiconductor epitaxial stack structure. However, the sapphire and silicon carbide substrates represent fatal problems to obtain the high-performance electronic and optoelectronic devices using the GaN-based semiconductor epitaxial stack structure.

First, according to the GaN-based semiconductor epitaxial stack structure formed on the upper portion of the sapphire substrate, high-density crystalline defects, such as dislocation and stacking fault, may occur in the GaN-based semiconductor epitaxial stack structure due to the difference of the lattice constant and thermal expansion coefficient between the GaN-based semiconductor epitaxial stack structure and the sapphire substrate, thereby degrading the reliability of the device and making it difficult to fabricate or operate the GaN-based electronic and optoelectronic devices.

In addition, since the sapphire substrate has inferior thermal conductivity, the optoelectronic devices employing the GaN-based semiconductor epitaxial stack structure formed on the upper portion of the sapphire substrate do not easily emit heat to the exterior during the operation thereof, so that the life span of the devices may be shortened and the reliability of the devices may be degraded.

In addition to the above problems, due to the electrical insulating characteristic of the sapphire substrate, vertical-structured optoelectronic devices, which have been regarded as ideal optoelectronic devices, may not be achieved. For this reason, the MESA-structured optoelectronic devices causing the high cost and low performance must be fabricated by performing the dry etching and photolithography processes.

Although the SiC substrate is advantageous than the sapphire substrate having the electrical insulating property, the SiC substrate also represents several technical and economical disadvantages.

In particular, high costs may be incurred to fabricate single-crystalline silicon carbide, which is necessary to realize the electronic and optoelectronic devices employing the high-performance GaN-based semiconductor. In addition, since light generated from the active layer of the LED is mostly absorbed in the SiC substrate, the SiC substrate is not suitable for the next-generation LED having high efficiency.

To solve the above technical and economical problems derived from the hetero-substrates, various study groups have suggested methods of fabricating homo-substrates including GaN and AlN using the HVPE (hydride vapor phase epitaxy) method (see, phys. stat. sol. (c) No 6, 16271650, 2003).

In addition, a method of fabricating a thick III-nitride-based epitaxial substrate has been suggested. According to this method, a thick III-nitride-based epitaxial layer having a thickness of about 300 □ is formed on the upper portion of the sapphire substrate through the HVPE method, and a strong laser beam is irradiated to remove the sapphire substrate through the LLO scheme. Then, the post-treatment process is performed to obtain the thick III-nitride-based epitaxial substrate (see, phys. Stat. sol. (c) No 7, 1985-1988, 2003).

Besides the above conventional methods, another method of fabricating a thick III-nitride-based epitaxial substrate has been suggested to provide a GaN-based semiconductor epitaxial stack structure. According to this method, zinc oxide (ZnO), which has superior electric conductivity, represents similar lattice constant and thermal expansion coefficient, and is easily soluble through wet etching, is introduced into an original growth substrate or onto a sapphire substrate as a sacrificial layer when growing the GaN-based semiconductor epitaxial stack structure to form the high-quality GaN-based semiconductor epitaxial stack structure. Then, the sapphire substrate is removed through wet etching.

However, the above-described methods and technologies used for the III-nitride-based epitaxial growth substrate represent the technical difficulty, high cost, low quality, and low product yield, so the future prospect of the high-performance electronic and optoelectronic devices employing the nitride-based semiconductor epitaxial stack structure is unclear.

### DISCLOSURE OF INVENTION

### Technical Problem

The present invention provides a semiconductor device having high brightness.

The present invention also provides a method of manufacturing such a semiconductor device.

### Technical Solution

In one aspect of the present invention, a semiconductor device includes: a growth substrate having an insulating property; a nucleation layer formed on the growth substrate; an undoped buffering nitride-based layer formed on the nucleation layer while serving as a buffering layer; a first type nitride-based cladding layer formed on the undoped buffering nitride-based layer; a multi quantum well nitride-based active layer formed on the first type nitride-based cladding layer; a second type nitride-based cladding layer formed on the multi quantum well nitride-based active layer, the second type being different from the first type; and a tunnel junction layer formed between the undoped buffering nitride-based layer and the first type nitride-based cladding layer or formed on the second type nitride-based cladding layer or formed both between the undoped buffering nitride-based layer and the first type nitride-based cladding layer and formed on the second type nitride-based cladding layer.

In another aspect of the present invention, a semiconductor device includes a growth substrate having an insulating property; a nitride-based semiconductor thin film layer formed on the growth substrate; a supporting substrate layer formed on the nitride-based semiconductor thin film layer; and a light emitting structure formed on the supporting substrate layer.

The supporting substrate layer includes an AlN-based material layer prepared as a single layer or a multi-layer.

The supporting substrate layer includes metal, nitride, oxide, boride, carbide, silicide, oxy-nitride, and carbon nitride prepared as a single layer or a multi-layer.

The supporting substrate layer is prepared in a form of a single layer, or a multi-layer including an AlaObNc (a, b and c are integers) and a GaxOy (x and y are integers).

The supporting substrate layer is prepared in a form of a single layer, or a multi-layer including SiaAlbNcCd-based material (a, b, c and d are integers).

In still another aspect of the present invention, a semiconductor device includes a thick film layer; a first epitaxial layer formed on the thick film layer, in which a top surface of the first epitaxial layer is surface-treated; and second epitaxial layer formed on the first epitaxial layer and having a multi-layer including nitride-based semiconductors for electronic and optoelectronic devices, wherein each of the first and second epitaxial layer is prepared in a form of a single layer or a multi-layer including at least one compound expressed as InxAlyGazN (x, y and z are integers) or SixCyNz (x, y and z are integers).

In still yet another aspect of the present invention, a method for manufacturing a semiconductor device comprising: forming a first epitaxial layer on a growth substrate having an insulating property; depositing a thick film layer having a thickness of 30 □ or more on the first epitaxial layer; removing the growth substrate by using a laser beam; and treating a surface of the first epitaxial layer, which is exposed as the growth substrate is removed.

### Advantageous Effects

The semiconductor device according to the present invention exhibits high-quality, large area, high brightness, and high capacity. In addition, the layers or the light emitting structure provided in the semiconductor device of the present invention cannot be thermally or mechanically deformed or dissolved. Further, the semiconductor device according to the present invention may employ a high-performance semiconductor epitaxial layer.

### BRIEF DESCRIPTION OF THE DRAWINGS

FIGS. 1 and 2 are sectional views showing p-down vertical-structured nitride-based light emitting devices fabricated by using a first tunnel junction layer introduced into an upper portion of an undoped nitride-based layer serving as a buffering layer according to a first embodiment of the present invention;

FIGS. 3 and 4 are sectional views showing p-down vertical-structured nitride-based light emitting devices fabricated by using a first tunnel junction layer introduced into an upper portion of an undoped nitride-based layer serving as a buffering layer according to a second embodiment of the present invention;

FIGS. 5 and 6 are sectional views showing p-down vertical-structured nitride-based light emitting devices fabricated by using a second tunnel junction layer introduced into an upper portion of a p-type nitride-based cladding layer according to a third embodiment of the present invention;

FIGS. 7 and 8 are sectional views showing p-down vertical-structured nitride-based light emitting devices fabricated by using a second tunnel junction layer introduced into an upper portion of a p-type nitride-based cladding layer according to a fourth embodiment of the present invention;

FIGS. 9 and 10 are sectional views showing p-down vertical-structured nitride-based light emitting devices fabricated by using first and second tunnel junction layers introduced into upper portions of an undoped nitride-based layer serving as a buffering layer and a p-type nitride-based cladding layer according to a fifth embodiment of the present invention;

FIGS. 11 and 12 are sectional views showing p-down vertical-structured nitride-based light emitting devices fabricated by using first and second tunnel junction layers introduced into upper portions of an undoped nitride-based layer serving as a buffering layer and a p-type nitride-based cladding layer according to a sixth embodiment of the present invention;

FIGS. 13 and 14 are sectional views showing n-down vertical-structured nitride-based light emitting devices fabricated by using a first tunnel junction layer introduced into an upper portion of an undoped nitride-based layer serving as a buffering layer according to a seventh embodiment of the present invention;

FIGS. 15 and 16 are sectional views showing n-down vertical-structured nitride-based light emitting devices fabricated by using a second tunnel junction layer introduced into an upper portion of a p-type nitride-based cladding layer according to an eighth embodiment of the present invention;

FIGS. 17 and 18 are sectional views showing n-down vertical-structured nitride-based light emitting devices fabricated by using a second tunnel junction layer introduced into an upper portion of a p-type nitride-based cladding layer according to a ninth embodiment of the present invention;

FIGS. 19 and 20 are sectional views showing n-down vertical-structured nitride-based light emitting devices fabricated by using first and second tunnel junction layers introduced into upper portions of an undoped nitride-based layer serving as a buffering layer and a p-type nitride-based cladding layer according to a tenth embodiment of the present invention;

FIGS. 21 and 22 are sectional views showing n-down vertical-structured nitride-based light emitting devices fabricated by using first and second tunnel junction layers introduced into upper portions of an undoped nitride-based layer serving as a buffering layer and a p-type nitride-based cladding layer according to an eleventh embodiment of the present invention;

FIGS. 23 and 24 are sectional views showing a III-nitride-based thin film layer having a stack structure of a nitride-based sacrificial layer and a nitride-based flattening layer and being formed on an upper portion of a sapphire substrate, which is an insulating growth substrate, and a supporting substrate layer formed on the III-nitride-based thin film layer according to a twelfth embodiment of the present invention;

FIGS. 25 and 26 are sectional views showing a III-nitride-based thin film layer and a supporting substrate layer sequentially formed on an upper portion of a sapphire substrate, which is an insulating growth substrate, in which another III-nitride-based thin film layer for a growth substrate and a nitride-based light emitting structure layer are grown from an upper portion of the resultant structure according to a thirteenth embodiment of the present invention;

FIGS. 27 to 30 are sectional views showing a supporting substrate layer, a nitride-based thin film layer formed on the supporting substrate layer for a growth substrate, and a III-nitride-based light emitting structure layer formed on the nitride-based thin film layer after a sapphire substrate, which is an insulating growth substrate, has been removed through a laser lift-off (LLO) scheme according to a fourteenth embodiment of the present invention;

FIGS. 31 to 34 are sectional views showing four types of nitride-based light emitting structure layers formed on a supporting substrate layer after a sapphire substrate, which is an insulating growth substrate, has been removed through a laser lift-off (LLO) scheme according to a fifteenth embodiment of the present invention;

FIGS. 35 to 39 are sectional views showing two p-down vertical-structured nitride-based light emitting devices and three n-down vertical-structured nitride-based light emitting devices fabricated by employing a supporting substrate layer and a laser lift-off (LLO) scheme according to a sixteenth embodiment of the present invention;

FIGS. 40 to 43 are sectional views showing two p-down vertical-structured nitride-based light emitting devices and two n-down vertical-structured nitride-based light emitting devices fabricated by employing a supporting substrate layer, a first tunnel junction layer and a laser lift-off (LLO) scheme according to a seventeenth embodiment of the present invention;

FIGS. 44 to 50 are sectional views showing four p-down vertical-structured nitride-based light emitting devices and three n-down vertical-structured nitride-based light emitting devices fabricated by employing a supporting substrate layer, a second tunnel junction layer and a laser lift-off (LLO) scheme according to an eighteenth embodiment of the present invention;

FIGS. 51 to 56 are sectional views showing four p-down vertical-structured nitride-based light emitting devices and two n-down vertical-structured nitride-based light emitting devices fabricated by employing a supporting substrate layer, first and second tunnel junction layers and a laser lift-off (LLO) scheme according to a nineteenth embodiment of the present invention;

FIGS. 57 and 58 are sectional views showing an AlN-based supporting substrate layer formed on a III-nitride-based sacrificial layer or on a nitride-based thin film layer including a stacked structure of a nitride-based sacrificial layer and a nitride-based flattening layer formed on an upper portion of a sapphire substrate, which is an insulating growth substrate, according to a twentieth embodiment of the present invention;

FIGS. 59 and 60 are sectional views showing a nitride-based thick film layer for a high-quality growth substrate, which is grown at the temperature of 800° C. or above on an upper portion of a structure where a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-first embodiment of the present invention;

FIGS. 61 and 62 are sectional views showing a nitride-based thin nucleation layer grown at the temperature less than 800° C., and a nitride-based thick film layer grown at the temperature of 800° C. or above to provide a thick layer for a high-quality growth substrate, in which the nitride-based thin nucleation layer and the nitride-based thick film layer are sequentially formed on an upper portion of a structure where a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-second embodiment of the present invention;

FIGS. 63 and 64 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-third embodiment of the present invention;

FIGS. 65 and 66 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-fourth embodiment of the present invention;

FIGS. 67 and 68 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-fifth embodiment of the present invention;

FIGS. 69 and 70 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-sixth embodiment of the present invention;

FIG. 71 is a process flowchart showing the manufacturing process of a high-quality p-side down light emitting diode according to a twenty-seventh embodiment of the present invention, in which the high-quality p-side down light emitting diode is manufactured by using the LED stack structures according to the twenty-third to twenty-sixth embodiments of the present invention in such a manner that a p-type nitride cladding layer can be located below an n-type nitride cladding layer;

FIGS. 72 to 75 are sectional views showing a high-quality p-side down light emitting diode according to a twenty-eighth embodiment of the present invention, in which the high-quality p-side down light emitting diode is manufactured according to the flowchart shown in FIG. 71 by using the LED stack structures according to the twenty-third embodiment of the present invention;

FIGS. 76 to 79 are sectional views showing a high-quality p-side down light emitting diode according to a twenty-ninth embodiment of the present invention, in which the high-quality p-side down light emitting diode is manufactured according to the flowchart shown in FIG. 71 by using the LED stack structures according to the twenty-fourth embodiment of the present invention;

FIGS. 80 to 83 are sectional views showing a high-quality p-side down light emitting diode according to a thirtieth embodiment of the present invention, in which the high-quality p-side down light emitting diode is manufactured according to the flowchart shown in FIG. 71 by using the LED stack structures according to the twenty-fifth embodiment of the present invention;

FIGS. 84 to 87 are sectional views showing a high-quality p-side down light emitting diode according to a thirty-first embodiment of the present invention, in which the high-quality p-side down light emitting diode is manufactured according to the flowchart shown in FIG. 71 by using the LED stack structures according to the twenty-sixth embodiment of the present invention;

FIG. 88 is a process flowchart showing the manufacturing process of a high-quality n-side down light emitting diode according to a thirty-second embodiment of the present invention, in which the high-quality n-side down light emitting diode is manufactured by using the LED stack structures according to the twenty-third to twenty-sixth embodiments of the present invention in such a manner that an n-type nitride cladding layer can be located below a p-type nitride cladding layer;

FIGS. 89 and 90 are sectional views showing a high-quality n-side down light emitting diode according to a thirty-third embodiment of the present invention, in which the high-quality n-side down light emitting diode is manufactured according to the flowchart shown in FIG. 88 by using the LED stack structures according to the twenty-third embodiment of the present invention;

FIGS. 91 and 92 are sectional views showing a high-quality n-side down light emitting diode according to a thirty-fourth embodiment of the present invention, in which the high-quality n-side down light emitting diode is manufactured according to the flowchart shown in FIG. 88 by using the LED stack structures according to the twenty-fourth embodiment of the present invention;

FIGS. 93 to 96 are sectional views showing a high-quality n-side down light emitting diode according to a thirty-fifth embodiment of the present invention, in which the high-quality n-side down light emitting diode is manufactured according to the flowchart shown in FIG. 88 by using the LED stack structures according to the twenty-fifth embodiment of the present invention;

FIGS. 97 to 100 are sectional views showing a high-quality n-side down light emitting diode according to a thirty-sixth embodiment of the present invention, in which the high-quality n-side down light emitting diode is manufactured according to the flowchart shown in FIG. 88 by using the LED stack structures according to the twenty-sixth embodiment of the present invention;

FIG. 101 is a process flowchart showing the manufacturing process of a high-quality n-side down light emitting diode according to a thirty-seventh embodiment of the present invention, in which the high-quality n-side down light emitting diode is manufactured by using the LED stack structures according to the twenty-third to twenty-sixth embodiments of the present invention in such a manner that an n-type nitride cladding layer can be located below a p-type nitride cladding layer;

FIGS. 102 to 105 are sectional views showing a high-quality n-side down light emitting diode according to a thirty-eighth embodiment of the present invention, in which the high-quality n-side down light emitting diode is manufactured through a bonding transfer scheme according to the flowchart shown in FIG. 101 by using the LED stack structures according to the twenty-third embodiment of the present invention;

FIGS. 106 to 109 are sectional views showing a high-quality n-side down light emitting diode according to a thirty-ninth embodiment of the present invention, in which the high-quality n-side down light emitting diode is manufactured through an electroplating scheme according to the flowchart shown in FIG. 101 by using the LED stack structures according to the twenty-third embodiment of the present invention;

FIGS. 110 to 113 are sectional views showing a high-quality n-side down light emitting diode according to a fortieth embodiment of the present invention, in which the high-quality n-side down light emitting diode is manufactured through a bonding transfer scheme according to the flowchart shown in FIG. 101 by using the LED stack structures according to the twenty-fourth embodiment of the present invention;

FIGS. 114 to 117 are sectional views showing a high-quality n-side down light emitting diode according to a forty-first embodiment of the present invention, in which the high-quality n-side down light emitting diode is manufactured through an electroplating scheme according to the flowchart shown in FIG. 101 by using the LED stack structures according to the twenty-fourth embodiment of the present invention;

FIGS. 118 to 121 are sectional views showing a high-quality n-side down light emitting diode according to a forty-second embodiment of the present invention, in which the high-quality n-side down light emitting diode is manufactured through a bonding transfer scheme according to the flowchart shown in FIG. 101 by using the LED stack structures according to the twenty-fifth embodiment of the present invention;

FIGS. 122 to 125 are sectional views showing a high-quality n-side down light emitting diode according to a forty-third embodiment of the present invention, in which the high-quality n-side down light emitting diode is manufactured through an electroplating scheme according to the flowchart shown in FIG. 101 by using the LED stack structures according to the twenty-fifth embodiment of the present invention;

FIGS. 126 to 129 are sectional views showing a high-quality n-side down light emitting diode according to a forty-fourth embodiment of the present invention, in which the high-quality n-side down light emitting diode is manufactured through a bonding transfer scheme according to the flowchart shown in FIG. 101 by using the LED stack structures according to the twenty-sixth embodiment of the present invention;

FIGS. 130 to 133 are sectional views showing a high-quality n-side down light emitting diode according to a forty-fifth embodiment of the present invention, in which the high-quality n-side down light emitting diode is manufactured through an electroplating scheme according to the flowchart shown in FIG. 101 by using the LED stack structures according to the twenty-sixth embodiment of the present invention;

FIGS. 134 to 138 are sectional views showing the procedure of forming an epitaxial stack structure on a substrate for electronic and optoelectronic devices employing GaN-based semiconductors to provide a high quality epitaxial substrate according to a forty-sixth embodiment of the present invention;

FIGS. 139 to 144 are sectional views showing the procedure of forming an epitaxial stack structure on a substrate for electronic and optoelectronic devices employing GaN-based semiconductors to provide a high quality epitaxial substrate according to a forty-seventh embodiment of the present invention;

FIG. 145 is a sectional view showing first and second epitaxial stack structures sequentially formed on a thick film layer according to a forty-eighth embodiment of the present invention; and

FIG. 146 is a sectional view showing first and second epitaxial stack structures sequentially formed on a thick film layer according to a forty-ninth embodiment of the present invention.

### MODE FOR THE INVENTION

Hereinafter, exemplary embodiments of the present invention will be described with reference to accompanying drawings.

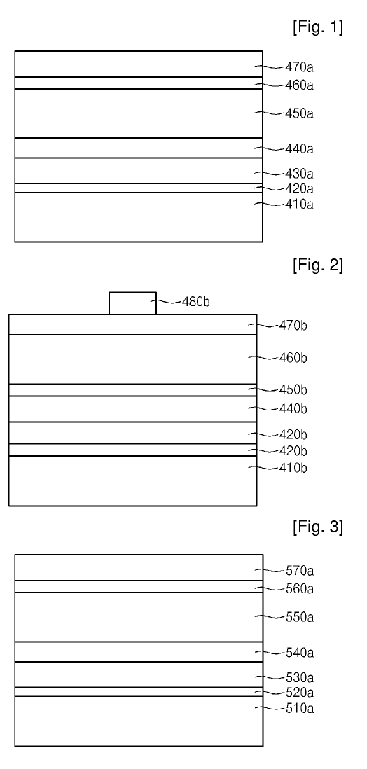

FIGS. 1 and 2 are sectional views showing p-down vertical-structured nitride-based light emitting devices fabricated by using a first tunnel junction layer introduced into an upper portion of an undoped nitride-based layer serving as a buffering layer according to a first embodiment of the present invention.

As shown in FIG. 1, in order to fabricate a nitride-based light emitting device having the large area, high capacity and high brightness according to the present invention, a nucleation layer 420a including amorphous GaN or AlN formed at the temperature of 600° C. or below is deposited on a sapphire substrate 410a, which is an insulating growth substrate, at a thickness of 100 nm or less. Then, after forming an undoped nitride-based layer 430a serving as a buffer layer and having a thickness of 3 nm or less, a high-quality first tunnel junction layer 440a is formed on the undoped nitride-based layer 430a. After that, an n-type nitride-based thin cladding layer 450a, a multi-quantum well nitride-based active layer 460a, and a p-type nitride-based cladding layer 470a are sequentially formed to provide a high quality nitride-based light emitting structure.

Different from the vertical-structured nitride-based LED as it can be fabricated through the laser lift-off (LLO) scheme, the above nitride-based light emitting structure includes the first tunnel junction layer 440a formed on the undoped nitride-based layer 430a.

The p-down vertical-structured nitride-based LED fabricated by using the nitride-based light emitting structure shown in FIG. 1 and the LLO scheme is shown in FIG. 2 in detail.

Referring to FIG. 2, the p-down vertical-structured nitride-based LED includes a supporting substrate 410b, a bonding material layer 420b, a p-reflective ohmic contact layer 430b, a p-type nitride-based cladding layer 440b, a multi-quantum well nitride-based active layer 450b, an n-type nitride-based cladding layer 460b, a first tunnel junction layer 470a, and an n-electrode pad 480b.

The supporting substrate 410b, which serves as a heat sink to protect the light emitting structure and to emit heat when the thin nitride-based light emitting structure is removed from the sapphire substrate through the LLO scheme, preferably includes metals, alloys or solid solution having superior electric and thermal conductivity. For example, instead of using a silicon substrate, the supporting substrate 410b includes silicide that is an intermetallic compound, aluminum (Al), Al-related alloy or solid solution, copper (Cu), Cu-related alloy or solid solution, silver (Ag), or Ag-related alloy or solid solution. Such a supporting substrate 410b can be fabricated through mechanical, electrochemical, physical or chemical deposition.

The present invention adopts the LLO scheme so as to remove the nitride-based light emitting structure from the sapphire substrate. Although the LLO scheme is conventionally performed under the normal temperature and normal pressure, according to the present invention, the LLO scheme is performed in a state in which the sapphire substrate is immersed in acid solution such as HCl or base solution having the temperature of 40° C. or more, in order to improve the product yield which may be lowered if crack of the nitride-based light emitting structure occurs during the process.

The bonding material layer 420b preferably includes metals having higher cohesion properties and low melting points, such as indium (In), tin (Sn), zinc (Zn), silver (Ag), palladium (Pd), or gold (Au), and alloys or solid solution of the above metals.

The p-reflective ohmic contact layer 430b may include a thick layer of Ag and Rh without using Al and Al-related alloy or solid solution, which is a high reflective material that represents low specific contact resistance and high light reflectance on the p-nitride-based cladding layer. In addition, the p-reflective ohmic contact layer 430b may include a dual reflective layer or a triple reflective layer including the high reflective metal combined with nickel (Ni), palladium (Pd), platinum (Pt), zinc (Zn), magnesium (Mg), or gold (Au). Further, the p-reflective ohmic contact layer 430b may include a combination of transparent conductive oxide (TCO), transitional metal-based transparent conductive nitride, and the high reflective metal. Aluminum, Al-related alloy and Al-related solid solution are more prefer than other high reflective metals, alloys, and solid solution thereof.

Each of the p-type nitride-based cladding layer 440b, the multi-quantum well nitride-based active layer 450b, and the n-type nitride-based cladding layer 460b basically includes one selected from compounds expressed as AlxInyGazN (x, y, and z are integers) which is a general formula of III-nitride-based compound. Dopants are added to the p-type nitride-based cladding layer 440b and the n-type nitride-based cladding layer 460b.

In addition, the nitride-based active layer 450b can be prepared in the form of a single layer or a multi-quantum well (MQW) structure.

For instance, if GaN-based compound is employed, the n-type nitride-based cladding layer 460b includes GaN and n-type dopants added to GaN, such as Si, Ge, Se, Te, etc., and the nitride-based active layer 450b has an InGaN/GaN MQW structure or an AlGaN/GaN MQW structure. In addition, the p-type nitride-based cladding layer 440b includes GaN and p-type dopants added to GaN, such as Mg, Zn, Ca, Sr, Ba, Be, etc.

The first tunnel junction layer 470b basically includes one selected from compounds expressed as AlaInbGacNxPyAsz (a, b, c, x, y and z are integers) consisting of III-V group elements. The first tunnel junction layer 470b can be prepared in the form of a single layer having a thickness of 50 nm or less. Preferably, the first tunnel junction layer 470b is prepared in the form of a bi-layer, a tri-layer or a multi-layer.

Preferably, the first tunnel junction layer 470b has a super-lattice structure. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the first tunnel junction layer 470b may include an single-crystal layer, a poly-crystal layer or an amorphous layer having III-group elements (Mg, Be, Zn) or IV-group elements (Si, Ge) added thereto. In order to improve electrical and optical characteristics of the nitride-based light emitting device by providing a photonic crystal effect or by adjusting a roughness of an upper surface or a lower surface of the first tunnel junction layer 470b, a dot, a hole, a pyramid, a nano-rod, or a nano-columnar having a size of 10 nm or less can be provided through an interferometry scheme using interference of the laser beam and photo-reactive polymer or through an etching technology.

Another method of improving the electrical and optical characteristics of the nitride-based light emitting device through the surface roughness adjustment and photonic crystal effect has been suggested. This method is performed for 10 seconds to 1 hour at the temperature in a range of the normal temperature to 800° C. under oxygen (O₂), nitrogen (N₂), argon (Ar), or hydrogen (H₂) atmosphere.

The n-electrode pad 480b may have a stack structure including refractory metals, such as titanium (Ti), aluminum (Al), gold (Au) and tungsten (W) which are sequentially stacked.

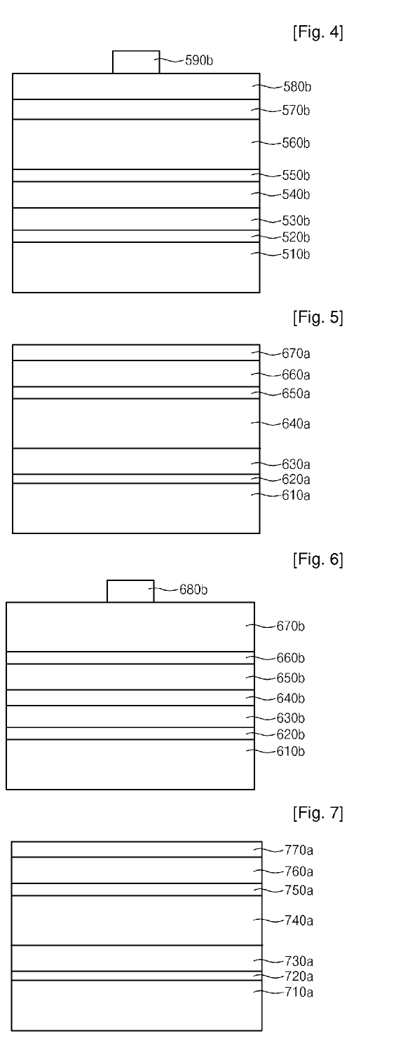

FIGS. 3 and 4 are sectional views showing p-down vertical-structured nitride-based light emitting devices fabricated by using a first tunnel junction layer introduced into an upper portion of an undoped nitride-based layer serving as a buffering layer according to a second embodiment of the present invention.

As shown in FIGS. 3 and 4, the nitride-based light emitting structure stacked on the insulating growth substrate and the p-down vertical-structured nitride-based light emitting device are substantially identical to those of the first embodiment, except for an n-type ohmic current spreading layer 580b, which is a high transparent conductive thin film layer formed on the first tunnel junction layer 570b.

Preferably, the high transparent conductive thin film layer formed on the first tunnel junction layer 570b, that is, the n-type ohmic current spreading layer 580b includes transparent conducive oxide (TCO) or transitional metal-based transparent conductive nitride (TCN). Here, TCO is transparent conductive compound including oxygen (O) combined with at least one selected from the group consisting of indium (In), tin (Sn), zinc (Zn), gallium (Ga), cadmium (Cd), magnesium (Mg), beryllium (Be), silver (Ag), molybdenum (Mo), vanadium (V), copper (Cu), iridium (Ir), rhodium (Rh), ruthenium (Ru), tungsten (W), titanium (Ti), tantalum (Ta), cobalt (Co), nickel (Ni), manganese (Mn), platinum (Pt), palladium (Pd), aluminum (Al), and lanthanum (La).

In addition, TCN is transparent conductive compound obtained by combining nitrogen (N) with titanium (Ti), tungsten (W), tantalum (Ta), vanadium (V), chrome (Cr), zirconium (Zr), niobium (Nb), hafnium (Hf), rhenium (Re) or molybdenum (Mo).

More preferably, the current spreading layers stacked on the n-type and p-type nitride-based cladding layers may be combined with metallic components that form new transparent conductive thin layers when the heat treatment process is performed in the nitrogen (N₂) or oxygen (O₂) atmosphere.

In order to improve the quality of the n-type ohmic current spreading layer 580b, the sputtering deposition process using plasma including oxygen (O₂), nitrogen (N₂), argon (Ar) or hydrogen (H₂), and the pulsed laser deposition (PLD) process using storing laser beam are primarily utilized. Besides these, electron-beam or thermal evaporation, atomic layer deposition (ALD), chemical vapor deposition (CVD), electroplating, or electrochemical deposition can be used. In particular, in the vertical-structured nitride-based light emitting devices obtained through the LLO scheme, ions having strong energy may exert bad influence upon the surface of the nitride-based cladding layer when the n-type or p-type ohmic current spreading layer is deposited on the nitride-based cladding layer. In order to avoid this problem, evaporator using the electron-beam or thermal resistance is preferably used.

In order to improve the electrical and optical characteristics of the nitride-based light emitting device by providing photonic crystal effect or by adjusting the surface roughness of the n-type or p-type ohmic contact layer or n-type or p-type ohmic current spreading layer, the above deposition is performed for 10 seconds to 1 hour at the temperature in a range of the normal temperature to 800° C. under oxygen (O₂), nitrogen (N₂), argon (Ar), or hydrogen (H₂) atmosphere.

Hereinafter, the third to eleventh embodiments of the present invention will be described. In the third to eleventh embodiments, some elements are identical to those of the first and second embodiments. Thus, the similar reference numerals are designated to the similar elements throughout the FIGS. 1 to 22, and the detailed description thereof will be omitted to avoid redundancy.

FIGS. 5 and 6 are sectional views showing p-down vertical-structured nitride-based light emitting devices fabricated by using a second tunnel junction layer introduced into an upper portion of a p-type nitride-based cladding layer according to a third embodiment of the present invention.

As shown in FIG. 5, in order to fabricate a nitride-based light emitting device having the large area, high capacity and high brightness according to the present invention, a nucleation layer 620a including amorphous GaN or AlN formed at the temperature of 600° C. or below is deposited on a sapphire substrate 610a, which is an insulating growth substrate, at a thickness of 100 nm or less. Then, after forming an undoped nitride-based layer 630a serving as a buffer layer and having a thickness of 3 nm or less, an n-type nitride-based thin cladding layer 640a, a multi-quantum well nitride-based active layer 650a, and a p-type nitride-based cladding layer 660a are sequentially formed on the undoped nitride-based layer 630a. After that, a second tunnel junction layer 670a is formed on the p-type nitride-based cladding layer 660a to provide a high quality nitride-based light emitting structure. Different from the vertical-structured nitride-based LED, which is fabricated through the laser lift-off (LLO) scheme, the above nitride-based light emitting structure includes the second tunnel junction layer 670a formed on the p-type nitride-based cladding layer 660a.

The p-down vertical-structured nitride-based LED fabricated by using the nitride-based light emitting structure shown in FIG. 5 and the LLO scheme is shown in FIG. 6 in detail.

Referring to FIG. 6, the nitride-based LED includes a supporting substrate 610b, a bonding material layer 620b, a p-reflective ohmic contact layer 630b, a second tunnel junction layer 640b, a p-type nitride-based cladding layer 650b, a multi-quantum well nitride-based active layer 660b, an n-type nitride-based cladding layer 670b, and an n-electrode pad 680b.

The second tunnel junction layer 640b basically includes one selected from compounds expressed as AlaInbGacNxPyAsz (a, b, c, x, y and z are integers) consisting of III-V group elements. The second tunnel junction layer 640b can be prepared in the form of a single layer having a thickness of 50 nm or less. Preferably, the second tunnel junction layer 640b is prepared in the form of a bi-layer, a tri-layer or a multi-layer.

Preferably, the second tunnel junction layer 640b has a super-lattice structure. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the second tunnel junction layer 640b may include a single crystal layer, a poly-crystal layer or an amorphous layer having III-group elements (Mg, Be, Zn) or IV-group elements (Si, Ge) added thereto.

Each of the p-type nitride-based cladding layer 650b, the multi-quantum well nitride-based active layer 660b, and the n-type nitride-based cladding layer 670b basically includes one selected from compounds expressed as AlxInyGazN (x, y, and z are integers) which is a general formula of III-nitride-based compound. Dopants are added to the p-type nitride-based cladding layer 650b and the n-type nitride-based cladding layer 670b.

In addition, the nitride-based active layer 660b can be prepared in the form of a single layer or a multi-quantum well (MQW) structure.

For instance, if GaN-based compound is employed, the n-type nitride-based cladding layer 670b includes GaN and n-type dopants added to GaN, such as Si, Ge, Se, Te, etc., and the nitride-based active layer 660b has an InGaN/GaN MQW structure or an AlGaN/GaN MQW structure. In addition, the p-type nitride-based cladding layer 650b includes GaN and p-type dopants added to GaN, such as Mg, Zn, Ca, Sr, Ba, Be, etc.

In order to improve electrical and optical characteristics of the nitride-based light emitting device by providing a photonic crystal effect or by adjusting a roughness of an upper surface of the n-type nitride-based cladding layer 670b, a dot, a hole, a pyramid, a nano-rod, or a nano-columnar having a size of 10 nm or less can be provided through an interferometry scheme using interference of the laser beam and photo-reactive polymer or through an etching technology.

Another method of improving the electrical and optical characteristics of the nitride-based light emitting device through the surface roughness adjustment and photonic crystal effect has been suggested. This method is performed for 10 seconds to 1 hour at the temperature in a range of the normal temperature to 800° C. under oxygen (O₂), nitrogen (N₂), argon (Ar), or hydrogen (H₂) atmosphere.

The n-electrode pad 680b may have a stack structure including refractory metals, such as titanium (Ti), aluminum (Al), gold (Au) and tungsten (W) which are sequentially stacked.

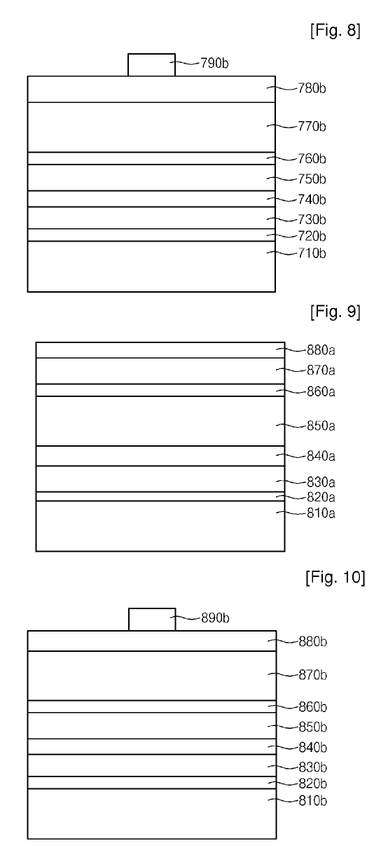

FIGS. 7 and 8 are sectional views showing p-down vertical-structured nitride-based light emitting devices fabricated by using a second tunnel junction layer introduced into an upper portion of a p-type nitride-based cladding layer according to a fourth embodiment of the present invention.

As shown in FIGS. 7 and 8, the nitride-based light emitting structure stacked on the insulating growth substrate and the p-down vertical-structured nitride-based LED using the same are substantially identical to those of the third embodiment, except for an n-type ohmic current spreading layer 780b, which is a high transparent conductive thin film layer formed on the n-type nitride-based cladding layer 770b. In addition, the high transparent conductive thin film layer formed on the n-type nitride-based cladding layer 770b is identical to that of the second embodiment.

FIGS. 9 and 10 are sectional views showing p-down vertical-structured nitride-based light emitting devices fabricated by using first and second tunnel junction layers introduced into upper portions of an undoped nitride-based layer serving as a buffering layer and a p-type nitride-based cladding layer according to a fifth embodiment of the present invention.

As shown in FIG. 9, in order to fabricate a nitride-based light emitting device having the large area, high capacity and high brightness according to the present invention, a nucleation layer 820a including amorphous GaN or AlN formed at the temperature of 600° C. or below is deposited on a sapphire substrate 810a, which is an insulating growth substrate, at a thickness of 100 nm or less. Then, after forming an undoped nitride-based layer 830a serving as a buffer layer and having a thickness of 3 nm or less, a high-quality first tunnel junction layer 840a is stacked on the undoped nitride-based layer 830a. Then, an n-type nitride-based thin cladding layer 850a, a multi-quantum well nitride-based active layer 860a, and a p-type nitride-based cladding layer 870a are sequentially formed on the high-quality first tunnel junction layer 840a. After that, a second tunnel junction layer 880a is formed on the p-type nitride-based cladding layer 870a to provide a high quality nitride-based light emitting structure.

Different from the vertical-structured nitride-based LED, which is fabricated through the laser lift-off (LLO) scheme, the above nitride-based light emitting structure includes the first and second tunnel junction layers 840a and 880a formed on the undoped nitride-based layer 830a and the p-type nitride-based cladding layer 880a, respectively.

The p-down vertical-structured nitride-based LED fabricated by using the nitride-based light emitting structure shown in FIG. 9 and the LLO scheme is shown in FIG. 10 in detail.

Referring to FIG. 10, the nitride-based LED includes a supporting substrate 810b, a bonding material layer 820b, a p-reflective ohmic contact layer 830b, a second tunnel junction layer 840b, a p-type nitride-based cladding layer 850b, a multi-quantum well nitride-based active layer 860b, an n-type nitride-based cladding layer 870b, a first tunnel junction layer 880b and an n-electrode pad 890b.

Each of the p-type nitride-based cladding layer 850b, the multi-quantum well nitride-based active layer 860b, and the n-type nitride-based cladding layer 870b basically includes one selected from compounds expressed as AlxInyGazN (x, y, and z are integers), which is a general formula of III-nitride-based compound. Dopants are added to the p-type nitride-based cladding layer 850b and the n-type nitride-based cladding layer 870b. In addition, the nitride-based active layer 860b can be prepared in the form of a single layer or a multi-quantum well (MQW) structure.

The n-electrode pad 890b may have a stack structure including refractory metals, such as titanium (Ti), aluminum (Al), gold (Au) and tungsten (W) which are sequentially stacked.

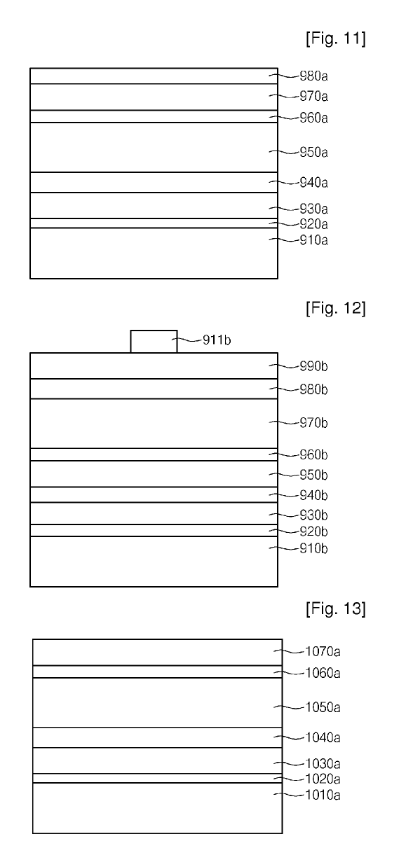

FIGS. 11 and 12 are sectional views showing p-down vertical-structured nitride-based light emitting devices fabricated by using first and second tunnel junction layers introduced into upper portions of an undoped nitride-based layer serving as a buffering layer and a p-type nitride-based cladding layer according to a sixth embodiment of the present invention.

As shown in FIGS. 11 and 12, the nitride-based light emitting structure stacked on the insulating growth substrate and the p-down vertical-structured nitride-based LED using the same are substantially identical to those of the fifth embodiment, except for a first tunnel junction layer 980b stacked on an n-type nitride-based cladding layer 970b and an n-type ohmic current spreading layer 990b, which is a high transparent conductive thin film layer formed on the first tunnel junction layer 980b.

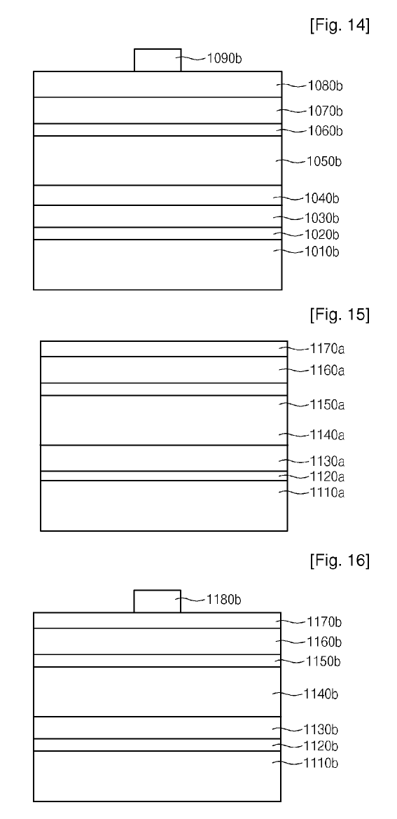

FIGS. 13 and 14 are sectional views showing n-down vertical-structured nitride-based light emitting devices fabricated by using a first tunnel junction layer introduced into an upper portion of an undoped nitride-based layer serving as a buffering layer according to a seventh embodiment of the present invention.

As shown in FIG. 13, in order to fabricate a nitride-based light emitting device having the large area, high capacity and high brightness according to the present invention, a nucleation layer 1020a including amorphous GaN or AlN formed at the temperature of 600° C. or below is deposited on a sapphire substrate 1010a, which is an insulating growth substrate, at a thickness of 100 nm or less. Then, after forming an undoped nitride-based layer 1030a serving as a buffer layer and having a thickness of 3 nm or less, a high-quality first tunnel junction layer 1040a is formed on the undoped nitride-based layer 1030a. After that, an n-type nitride-based thin cladding layer 1050a, a multi-quantum well nitride-based active layer 1060a, and a p-type nitride-based cladding layer 1070a are sequentially formed to provide a high quality nitride-based light emitting structure.

Different from the vertical-structured nitride-based LED as it can be fabricated through the laser lift-off (LLO) scheme, the above nitride-based light emitting structure includes the first tunnel junction layer 1040a formed on the undoped nitride-based layer 1030a.

The n-down vertical-structured nitride-based LED fabricated by using the nitride-based light emitting structure shown in FIG. 13 and the LLO scheme is shown in FIG. 14 in detail.

Referring to FIG. 14, the nitride-based LED includes a supporting substrate 1010b, a bonding material layer 1020b, an n-reflective ohmic contact layer 1030b, a first tunnel junction layer 1040a, an n-type nitride-based cladding layer 1050b, a multi-quantum well nitride-based active layer 1060b, a p-type nitride-based cladding layer 1070b, a p-type ohmic current spreading layer 1080b, and an n-electrode pad 1090b.

The n-reflective ohmic contact layer 1030b may include a thick layer of Ag, Rh or Al, which is a high reflective metal that represents low specific contact resistance and high light reflectance. The n-reflective ohmic contact layer 1030b may include alloys or solid solution based on the high reflective metals. In addition, the n-reflective ohmic contact layer 1030b may include a dual reflective layer or a triple reflective layer including the high reflective metal combined with nickel (Ni), palladium (Pd), platinum (Pt), zinc (Zn), magnesium (Mg), or gold (Au). Further, the n-reflective ohmic contact layer 1030b may include a combination of transparent conductive oxide (TCO), transitional metal-based transparent conductive nitride, and the high reflective metal.

Each of the n-type nitride-based cladding layer 1050b, the multi-quantum well nitride-based active layer 1060b, and the p-type nitride-based cladding layer 1070b basically includes one selected from compounds expressed as AlxInyGazN (x, y, and z are integers) which is a general formula of III-nitride-based compound. Dopants are added to the n-type nitride-based cladding layer 1050b and the p-type nitride-based cladding layer 1070b.

In addition, the nitride-based active layer 1060b can be prepared in the form of a single layer or a multi-quantum well (MQW) structure.

For instance, if GaN-based compound is employed, the n-type nitride-based cladding layer 1050b includes GaN and n-type dopants added to GaN, such as Si, Ge, Se, Te, etc., and the nitride-based active layer 1060b has an InGaN/GaN MQW structure or an AlGaN/GaN MQW structure. In addition, the p-type nitride-based cladding layer 1070b includes GaN and p-type dopants added to GaN, such as Mg, Zn, Ca, Sr, Ba, Be, etc.

The high transparent conductive thin layer, that is, the p-type ohmic current spreading layer 1080b formed on the p-type nitride-based cladding layer 1070b is identical to that of the second embodiment.

FIGS. 15 and 16 are sectional views showing n-down vertical-structured nitride-based light emitting devices fabricated by using a second tunnel junction layer introduced into an upper portion of a p-type nitride-based cladding layer according to an eighth embodiment of the present invention.

As shown in FIG. 15, in order to fabricate a nitride-based light emitting device having the large area, high capacity and high brightness according to the present invention, a nucleation layer 1120a including amorphous GaN or AlN formed at the temperature of 600° C. or below is deposited on a sapphire substrate 1110a, which is an insulating growth substrate, at a thickness of 100 nm or less. Then, after forming an undoped nitride-based layer 1130a serving as a buffer layer and having a thickness of 3 nm or less, an n-type nitride-based thin cladding layer 1140a, a multi-quantum well nitride-based active layer 1150a, and a p-type nitride-based cladding layer 1160a are sequentially formed on the undoped nitride-based layer 1130a. Then, a second tunnel junction layer 1170a is formed on the p-type nitride-based cladding layer 1160a to provide a high quality nitride-based light emitting structure. Different from the vertical-structured nitride-based LED, which is fabricated through the laser lift-off (LLO) scheme, the above nitride-based light emitting structure includes the second tunnel junction layer 1170a formed on the p-type nitride-based cladding layer 1160a.

The n-down vertical-structured nitride-based LED fabricated by using the nitride-based light emitting structure shown in FIG. 15 and the LLO scheme is shown in FIG. 16 in detail.

Referring to FIG. 16, the nitride-based LED includes a supporting substrate 1110b. In addition, a bonding material layer 1120b, an n-reflective ohmic contact layer 1130b, an n-type nitride-based cladding layer 1140b, a multi-quantum well nitride-based active layer 1150b, a p-type nitride-based cladding layer 1160b, a second tunnel junction layer 1170b, and an n-electrode pad 1180b are sequentially stacked on the supporting substrate 1110b.

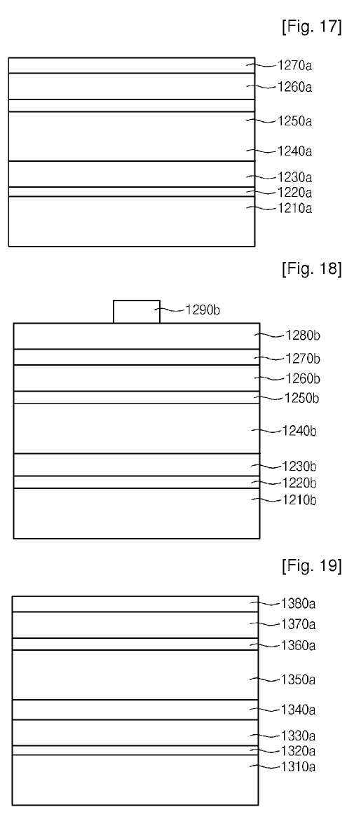

FIGS. 17 and 18 are sectional views showing n-down vertical-structured nitride-based light emitting devices fabricated by using a second tunnel junction layer introduced into an upper portion of a p-type nitride-based cladding layer according to a ninth embodiment of the present invention.

As shown in FIGS. 17 and 18, the nitride-based light emitting structure stacked on the insulating growth substrate and the n-down vertical-structured nitride-based light emitting device using the same are substantially identical to those of the eighth embodiment, except for a second tunnel junction layer 1270b stacked on a p-type nitride-based cladding layer 1260b and a p-type ohmic current spreading layer 1280b, which is a high transparent conductive thin film layer formed on the second tunnel junction layer 1270b.

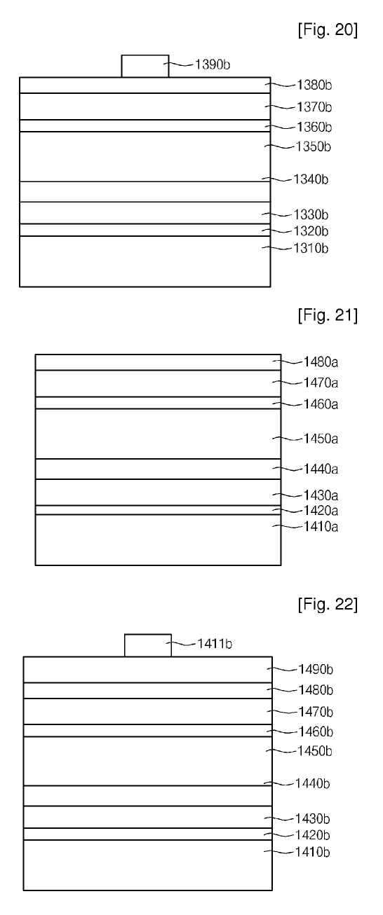

FIGS. 19 and 20 are sectional views showing n-down vertical-structured nitride-based light emitting devices fabricated by using first and second tunnel junction layers introduced into upper portions of an undoped nitride-based layer serving as a buffering layer and a p-type nitride-based cladding layer according to a tenth embodiment of the present invention.

As shown in FIG. 19, in order to fabricate a nitride-based light emitting device having the large area, high capacity and high brightness according to the present invention, a nucleation layer 1320a including amorphous GaN or AlN formed at the temperature of 600° C. or below is deposited on a sapphire substrate 1310a, which is an insulating growth substrate, at a thickness of 100 nm or less. Then, after forming an undoped nitride-based layer 1330a serving as a buffer layer and having a thickness of 3 nm or less, a high-quality first tunnel junction layer 1340a is formed on the undoped nitride-based layer 1330a. After that, an n-type nitride-based thin cladding layer 1350a, a multi-quantum well nitride-based active layer 1360a, and a p-type nitride-based cladding layer 1370a are sequentially formed on the high-quality first tunnel junction layer 1340a. Then, a second tunnel junction layer 1380a is formed on the p-type nitride-based cladding layer 1370a to provide a high quality nitride-based light emitting structure. Different from the vertical-structured nitride-based LED, which is fabricated through the laser lift-off (LLO) scheme, the above nitride-based light emitting structure includes the first and second tunnel junction layers 1340a and 1380a formed on the undoped nitride-based layer 1330a and the p-type nitride-based cladding layer 1370a, respectively.

The n-down vertical-structured nitride-based LED fabricated by using the nitride-based light emitting structure shown in FIG. 19 and the LLO scheme is shown in FIG. 20 in detail.

Referring to FIG. 20, the nitride-based LED includes a supporting substrate 1310b. In addition, a bonding material layer 1320b, an n-reflective ohmic contact layer 1330b, a first tunnel junction layer 1340b, an n-type nitride-based cladding layer 1350b, a multi-quantum well nitride-based active layer 1360b, a p-type nitride-based cladding layer 1370b, a second tunnel junction layer 1380b, and an p-electrode pad 1390b are sequentially stacked on the supporting substrate 1310b.

FIGS. 21 and 22 are sectional views showing n-down vertical-structured nitride-based light emitting devices fabricated by using first and second tunnel junction layers introduced into upper portions of an undoped nitride-based layer serving as a buffering layer and a p-type nitride-based cladding layer according to an eleventh embodiment of the present invention.

As shown in FIGS. 21 and 22, the nitride-based light emitting structure stacked on the insulating growth substrate and the n-down vertical-structured nitride-based LED using the same are substantially identical to those of the tenth embodiment, except for a second tunnel junction layer 1480b stacked on a p-type nitride-based cladding layer 1470b and a p-type ohmic current spreading layer 1490b, which is a high transparent conductive thin film layer formed on the second tunnel junction layer 1480b.

Hereinafter, embodiments of the present invention having supporting substrates capable of preventing the thin film layer or the light emitting structure from being thermally or mechanically deformed or decomposed will be described. In the following description, the same elements, such as the ohmic contact layer and the tunnel junction layer that have been described in the previous embodiments, may have the same function and structure if there are no special comments for them.

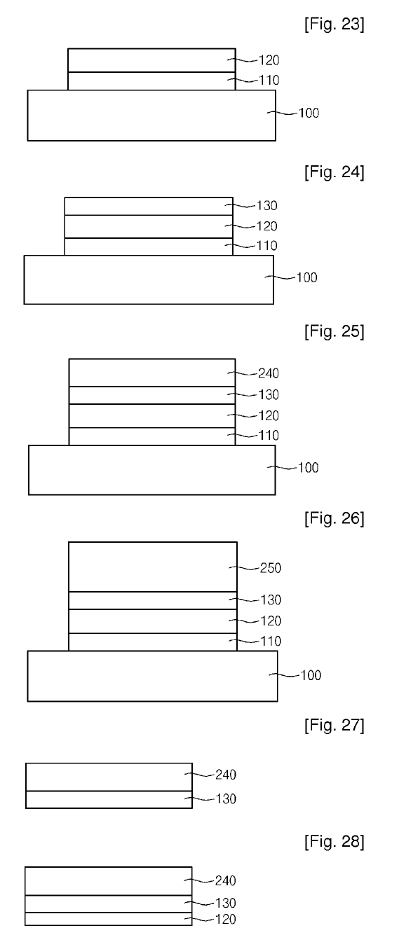

FIGS. 23 and 24 are sectional views showing a III-nitride-based thin film layer having a stack structure of a nitride-based sacrificial layer and a nitride-based flattening layer and being formed on an upper portion of a sapphire substrate, which is an insulating growth substrate, and a supporting substrate layer formed on the III-nitride-based thin film layer according to a twelfth embodiment of the present invention.

Referring to FIG. 23, a nitride-based sacrificial layer 110 including low-temperature GaN or AlN formed at the temperature of 700° C. or below with a thickness of 100 nm or less, and a nitride-based flattening layer 120 including GaN formed at the temperature of 800° C. or above to have a superior surface state are deposited and grown on a sapphire substrate 100, which is an initial growth substrate. In particular, when growing the nitride-based thin film layer or the nitride-based light emitting structure including III-nitride-based semiconductors, laser beams having strong energy are irradiated through a rear surface of the sapphire substrate. Thus, thermo-chemical decomposition reaction between Ga and N gas or Al and N₂ gas may occur at the nitride-based sacrificial layer 110, thereby facilitating release of the sapphire substrate 100.

Referring to FIG. 24, a supporting substrate layer 130 is stacked/grown on the nitride-based flattening layer 120 including III-nitride-based semiconductors. Such a supporting substrate layer 130 attenuate stress derived from thermal and mechanical deformation when removing the sapphire substrate 100, thereby preventing the nitride-based thin film layer or the light emitting structure grown on the supporting substrate layer 130 from being thermally and mechanically deformed or decomposed.

The supporting substrate layer 130 is prepared in the form of a single layer, a bi-layer or a tri-layer including SiaAlbNcCd (a, b, c and d are integers). An epitaxial layer, a poly-crystal layer or an amorphous material layer including SiC or SiCN, or having a chemical formula of SiCAIN is primarily applied to the supporting substrate layer 130.

In addition, preferably, the supporting substrate layer 130 is deposited at a thickness of 10 or less micrometers by means of chemical vapor deposition (CVD), such as metal organic chemical vapor deposition (MOCVD), sputtering deposition using gas ions having high energy, or physical vapor deposition (PVD), such as pulsed laser deposition (PLD) using a laser energy source.

Meanwhile, the supporting substrate layer 130 is prepared in the form of a single layer, a bi-layer or a tri-layer, such as AlaObNc (a, b and c are integers) or GaxOy (x and y are integers). Preferably, a single crystal layer having a hexagonal system, a poly-crystal layer, or an amorphous material layer having the chemical formula of Al₂O₃ or Ga₂O₃, is applied to the supporting substrate layer 130.

In this case, the supporting substrate layer 130 having insulating properties is deposited at a thickness of 10 or less by means of chemical vapor deposition (CVD) such as metal organic chemical vapor deposition (MOCVD), or physical vapor deposition (PVD) such as sputtering deposition using gas ions having high energy or pulsed laser deposition (PLD) using a laser energy source.

Meanwhile, the supporting substrate layer 130 may have a high melting point. In this case, the supporting substrate layer 130 having the high melting point is prepared in the form of a single layer, a bi-layer or a tri-layer regardless of the stacking order thereof. Preferably, a single crystal layer having a hexagonal system or a cubic system, a poly-crystal layer, or an amorphous material layer is primarily applied to the supporting substrate layer 130.

More preferably, supporting substrate layer 130 may include materials having reduction-resistant properties under a hydrogen atmosphere and or an ion atmospheres at the temperature of 1000° C. or above. Such materials include metal, nitride, oxide, boride, carbide, silicide, oxy-nitride, and carbon nitride.

In detail, the metal is selected from the group consisting of Ta, Ti, Zr, Cr, Sc, Si, Ge, W, Mo, Nb, and Al, the nitride is selected from the group consisting of Ti, V, Cr, Be, B, Hf, Mo, Nb, V, Zr, Nb, Ta, Hf, Al, B, Si, In, Ga, Sc, W, and rare-earth metal-based nitride, the oxide is selected from the group consisting of Ti, Ta, Li, Al, Ga, In, Be, Nb, Zn, Zr, Y, W, V, Mg, Si, Cr, La and rare-earth metal-based oxide, the boride is selected from the group consisting of Ti, Ta, Li, Al, Be, Mo, Hf, W, Ga, In, Zn, Zr, V, Y, Mg, Si, Cr, La and rare-earth metal-based boride, the carbide is selected from the group consisting of Ti, Ta, Li, B, Hf, Mo, Nb, W, V, Al, Ga, In, Zn, Zr, Y, Mg, Si, Cr, La and rare-earth metal-based carbide, the silicide is selected from the group consisting of Cr, Hf, Mo, Nb, Ta, Th, Ti, W, V, Zr and rare-earth metal-based silicide, the oxy-nitride includes Al—O—N and the carbon nitride includes Si—C—N.

In addition, preferably, the supporting substrate layer 130 having the high melting point is deposited at a thickness of 10 or less by means of chemical vapor deposition (CVD) such as metal organic chemical vapor deposition (MOCVD), or physical vapor deposition (PVD) such as sputtering deposition using gas ions having high energy and pulsed laser deposition (PLD) using a laser energy source.

FIGS. 25 and 26 are sectional views showing a III-nitride-based thin film layer and a supporting substrate layer sequentially formed on an upper portion of a sapphire substrate, which is an insulating growth substrate, in which another III-nitride-based thin film layer for a growth substrate and a nitride-based light emitting structure layer are grown from an upper portion of the resultant structure according to a thirteenth embodiment of the present invention.

Referring to FIGS. 25 and 26, a nitride-based sacrificial layer 110, a flattening layer 120, and a supporting substrate layer 130, which is prepared in the form of a single layer, a bi-layer or a tri-layer using epitaxy, poly-crystal or amorphous material, are sequentially formed on a sapphire substrate 100. In this state, another nitride-based thin film layer 240 and a nitride-based light emitting structure 250 are grown from an upper surface of the resultant structure.

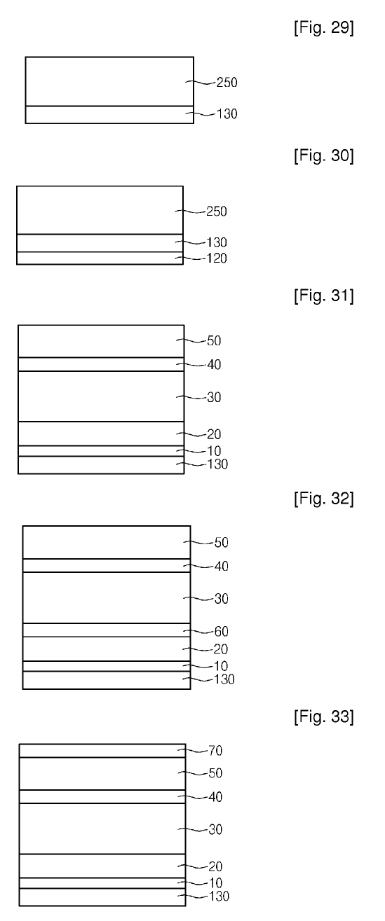

FIGS. 27 to 30 are sectional views showing a supporting substrate layer, a nitride-based thin film layer formed on the supporting substrate layer for a growth substrate, and a III-nitride-based light emitting structure layer formed on the nitride-based thin film layer after a sapphire substrate, which is an insulating growth substrate, has been removed through a laser lift-off (LLO) scheme according to a fourteenth embodiment of the present invention.

In particular, different from FIGS. 27 and 29, FIGS. 28 and 30 show the nitride-based flattening layer 120 that remains at a lower portion of the supporting substrate layer 130 even after the sapphire substrate 100 has been removed through the LLO scheme.

FIGS. 31 to 34 are sectional views showing four types of nitride-based light emitting structure layers formed on a supporting substrate layer after a sapphire substrate, which is an insulating growth substrate, has been removed through a laser lift-off (LLO) scheme according to a fifteenth embodiment of the present invention.

The nitride-based light emitting structure is primarily used for the LED and the LD. FIG. 31 shows a normal structure in which the tunnel junction layer is not introduced into the light emitting structure, and FIGS. 32 to 34 show the light emitting structure in which at least one tunnel junction layer 60 or 70 is formed at a lower portion of an n-type nitride-based cladding layer 30 or an upper portion of a p-type nitride-based cladding layer 50.

FIGS. 35 to 39 are sectional views showing two p-down vertical-structured nitride-based light emitting devices and three n-down vertical-structured nitride-based light emitting devices fabricated by employing a supporting substrate layer and a laser lift-off (LLO) scheme according to a sixteenth embodiment of the present invention.

In detail, similar to FIG. 31, FIGS. 35 to 39 show five types of nitride-based light emitting devices which include a nitride-based light emitting structure having a supporting substrate layer 130, on which a nucleation layer 10 including III-group nitride-based semiconductors, an undoped nitride-based layer 20 serving as a buffer layer, an n-type nitride-based cladding layer 30, a multi-quantum well nitride-based active layer 40, and a p-type nitride-based cladding layer 50 are sequentially formed. In addition, a heat sink 80 that emits heat generated during the operation of the light emitting device, a bonding layer 90, an ohmic current spreading layer 150 that directly makes contact with n-type and p-type nitride-based cladding layers 30 and 50, and a high reflective ohmic contact layer 140 are combined with the nitride-based light emitting structure.

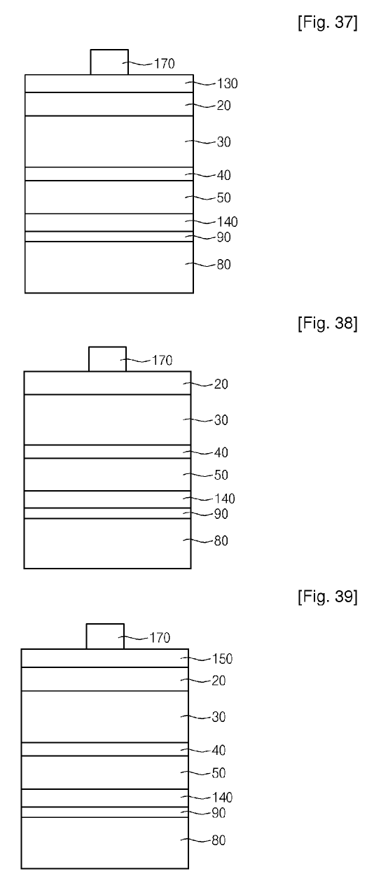

In particular, the nitride-based light emitting devices shown in FIGS. 35 and 37 are applicable if the supporting substrate layer 130 has superior electrical conductivity. Otherwise, the nitride-based light emitting devices shown in FIGS. 36, 38 and 39 are preferably used.

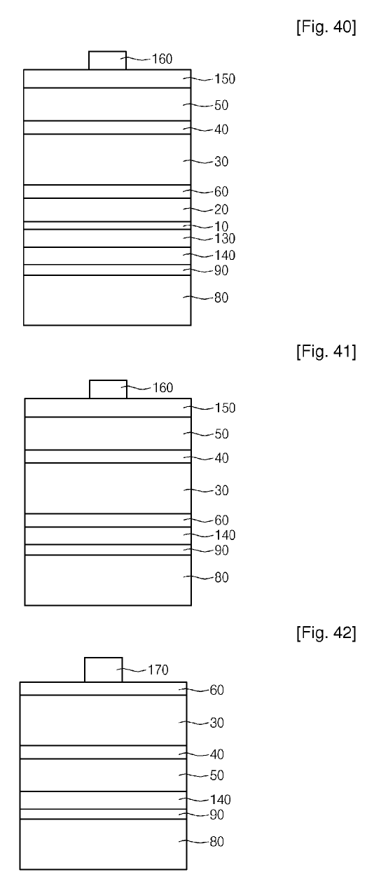

FIGS. 40 to 43 are sectional views showing two p-down vertical-structured nitride-based light emitting devices and two n-down vertical-structured nitride-based light emitting devices fabricated by employing a supporting substrate layer, a first tunnel junction layer and a laser lift-off (LLO) scheme according to a seventeenth embodiment of the present invention.

In detail, similar to FIG. 32, FIGS. 40 to 43 show four types of nitride-based light emitting devices which include a nitride-based light emitting structure having a supporting substrate layer 130, on which a nucleation layer 10 including III-group nitride-based semiconductors, an undoped buffering nitride-based layer 20 serving as a buffer layer, a first tunnel junction layer 60, an n-type nitride-based cladding layer 30, a multi-quantum well nitride-based active layer 40, and a p-type nitride-based cladding layer 50 are sequentially formed. In addition, a heat sink 80 that emits heat generated during the operation of the light emitting device, a bonding layer 90, an ohmic current spreading layer 150 that directly makes contact with n-type and p-type nitride-based cladding layers 30 and 50, and a high reflective ohmic contact layer 140 are combined with the nitride-based light emitting structure.

In particular, the nitride-based light emitting device shown in FIG. 40 is applicable if the supporting substrate layer 130 has superior electrical conductivity. Otherwise, the nitride-based light emitting devices shown in FIGS. 41 to 43 are preferably used.

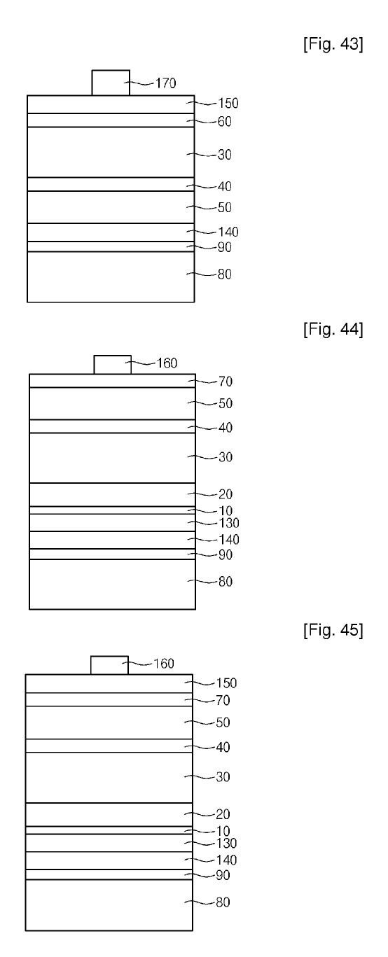

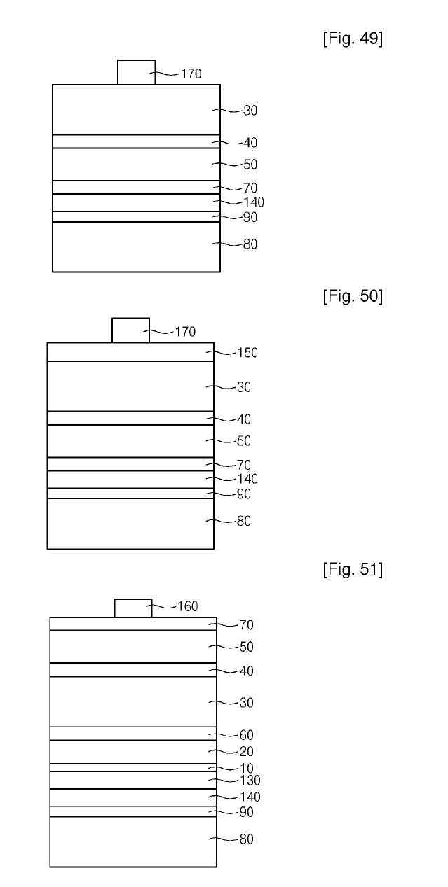

FIGS. 44 to 50 are sectional views showing four p-down vertical-structured nitride-based light emitting devices and three n-down vertical-structured nitride-based light emitting devices fabricated by employing a supporting substrate layer, a second tunnel junction layer and a laser lift-off (LLO) scheme according to an eighteenth embodiment of the present invention.

In detail, similar to FIG. 33, FIGS. 44 to 50 show seven types of nitride-based light emitting devices which include a nitride-based light emitting structure having a supporting substrate layer 130, on which a nucleation layer 10 including III-group nitride-based semiconductors, an undoped buffering nitride-based layer 20 serving as a buffer layer, an n-type nitride-based cladding layer 30, a multi-quantum well nitride-based active layer 40, a p-type nitride-based cladding layer 50, and a second tunnel junction layer 70 are sequentially formed. In addition, a heat sink 80 that emits heat generated during the operation of the light emitting device, a bonding layer 90, an ohmic current spreading layer 150 that directly makes contact with n-type and p-type nitride-based cladding layers 30 and 50, and a high reflective ohmic contact layer 140 are combined with the nitride-based light emitting structure.

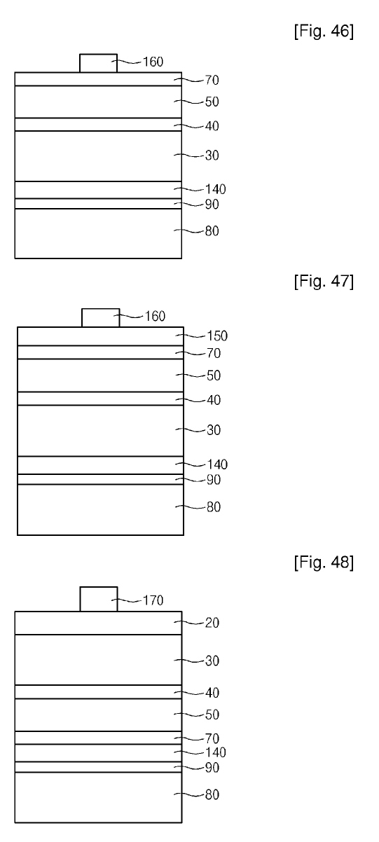

In particular, the nitride-based light emitting devices shown in FIGS. 44 and 45 are applicable if the supporting substrate layer 130 has superior electrical conductivity. Otherwise, the nitride-based light emitting devices shown in FIGS. 46 to 50 are preferably used.

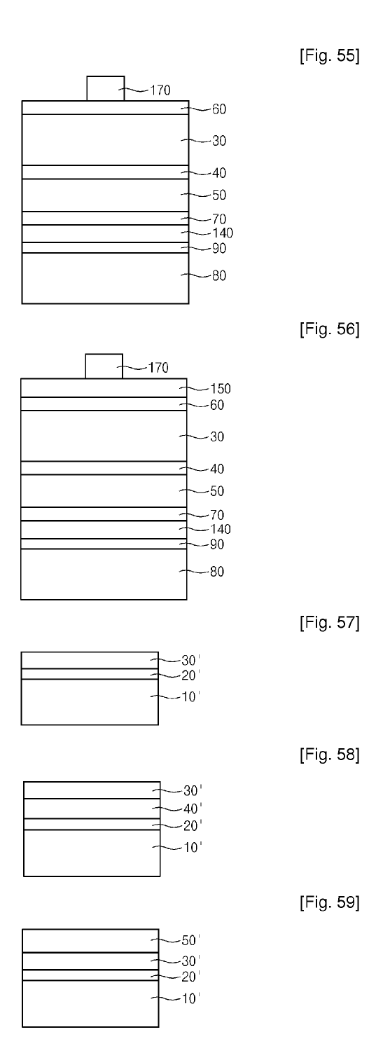

FIGS. 51 to 56 are sectional views showing four p-down vertical-structured nitride-based light emitting devices and two n-down vertical-structured nitride-based light emitting devices fabricated by employing a supporting substrate layer, first and second tunnel junction layers and a laser lift-off (LLO) scheme according to a nineteenth embodiment of the present invention.

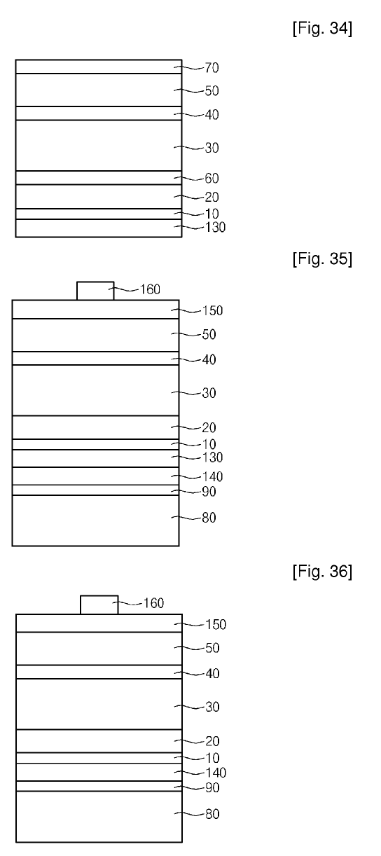

In detail, similar to FIG. 34, FIGS. 51 to 56 show six types of nitride-based light emitting devices which include a nitride-based light emitting structure having a supporting substrate layer 130, on which a nucleation layer 10 including III-group nitride-based semiconductors, an undoped buffering nitride-based layer 20 serving as a buffer layer, a first tunnel junction layer 60, an n-type nitride-based cladding layer 30, a multi-quantum well nitride-based active layer 40, a p-type nitride-based cladding layer 50, and a second tunnel junction layer 70 are sequentially formed. In addition, a heat sink 80 that emits heat generated during the operation of the light emitting device, a bonding layer 90, an ohmic current spreading layer 150 that directly makes contact with n-type and p-type nitride-based cladding layers 30 and 50, and a high reflective ohmic contact layer 140 are combined with the nitride-based light emitting structure.

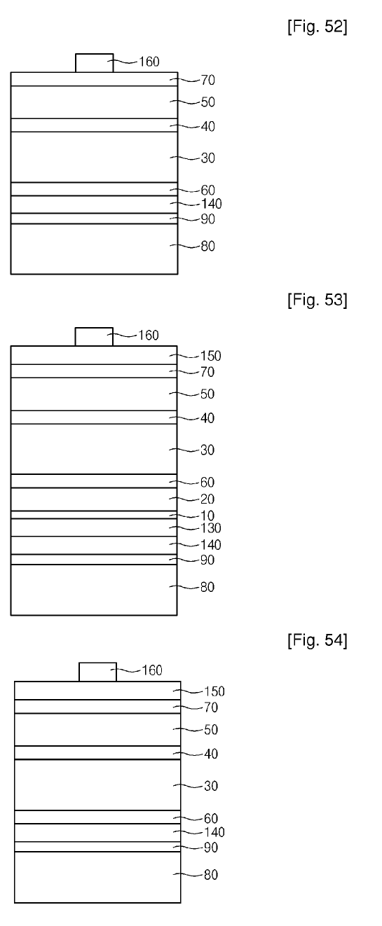

In particular, the nitride-based light emitting devices shown in FIGS. 51 and 52 are applicable if the supporting substrate layer 130 has superior electrical conductivity. Otherwise, the nitride-based light emitting devices shown in FIGS. 53 to 56 are preferably used.

As mentioned above, the supporting substrate 80, which serves as a heat sink to protect the light emitting structure used for the nitride-based light emitting device of the present invention and to emit heat, preferably includes metals, alloys or solid solution having superior electric and thermal conductivity. For example, instead of using a silicon substrate, the supporting substrate 80 includes silicide that is an intermetallic compound, aluminum (Al), Al-related alloy or solid solution, copper (Cu), Cu-related alloy or solid solution, silver (Ag), or Ag-related alloy or solid solution. Such a supporting substrate 80 can be fabricated through mechanical, electrochemical, physical or chemical deposition.

The present invention adopts the LLO scheme so as to remove the nitride-based light emitting structure from the insulating sapphire substrate 100. The LLO scheme is not performed under the normal temperature and normal pressure. According to the present invention, the LLO scheme is performed in a state in which the sapphire substrate is immersed in acid solution such as HCI or base solution having the temperature of 40 or more, in order to improve the product yield which may be lowered if crack of the nitride-based light emitting structure occurs during the process.

The bonding material layer 90 preferably includes metals having higher cohesion properties and low melting points, such as indium (In), tin (Sn), zinc (Zn), silver (Ag), palladium (Pd), or gold (Au), and alloys or solid solution of the above metals.

The p-reflective ohmic contact layer 140 may include a thick layer of Ag and Rh without using Al and Al-related alloy or solid solution, which is a high reflective material that represents low specific contact resistance and high light reflectance on the p-nitride-based cladding layer. In addition, the p-reflective ohmic contact layer 140 may include a dual reflective layer or a triple reflective layer including the high reflective metal combined with nickel (Ni), palladium (Pd), platinum (Pt), zinc (Zn), magnesium (Mg), or gold (Au). Further, the p-reflective ohmic contact layer 430b may include a combination of transparent conductive oxide (TCO), transitional metal-based transparent conductive nitride, and the high reflective metal.

Each of the p-type nitride-based cladding layer 50, the multi-quantum well nitride-based active layer 40, and the n-type nitride-based cladding layer 30 basically includes one selected from compounds expressed as AlxInyGazN (x, y, and z are integers) which is a general formula of III-nitride-based compound. Dopants are added to the p-type nitride-based cladding layer 50 and the n-type nitride-based cladding layer 30.

In addition, the nitride-based active layer 40 can be prepared in the form of a single layer or a multi-quantum well (MQW) structure.

For instance, if GaN-based compound is employed, the n-type nitride-based cladding layer 30 includes GaN and n-type dopants added to GaN, such as Si, Ge, Se, Te, etc., and the nitride-based active layer 40 has an InGaN/GaN MQW structure or an AlGaN/GaN MQW structure. In addition, the p-type nitride-based cladding layer 50 includes GaN and p-type dopants added to GaN, such as Mg, Zn, Ca, Sr, Ba, Be, etc.

The first and second tunnel junction layers 60 and 70 basically include one selected from compounds expressed as AlaInbGacNxPyAsz (a, b, c, x, y and z are integers) consisting of III-V group elements. The first and second tunnel junction layers 60 and 70 can be prepared in the form of a single layer having a thickness of 50 nm or less. Preferably, the first and second tunnel junction layers 60 and 70 are prepared in the form of a bi-layer, a tri-layer or a multi-layer.

Preferably, the first and second tunnel junction layers 60 and 70 have super-lattice structures. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the first and second tunnel junction layers 60 and 70 may include an epitaxial layer, a poly-crystal layer or an amorphous layer having III-group elements (Mg, Be Zn) or IV-group elements (Si, Ge) added thereto.

In order to improve electrical and optical characteristics of the nitride-based light emitting device by providing a photonic crystal effect or by adjusting a roughness of an upper surface or a lower surface of the first tunnel junction layer 470b, a dot, a hole, a pyramid, a nano-rod, or a nano-columnar having a size of 10 nm or less can be provided through an interferometry scheme using interference of the laser beam and photo-reactive polymer or through an etching technology.

Another method of improving the electrical and optical characteristics of the nitride-based light emitting device through the surface roughness adjustment and photonic crystal effect has been suggested. This method is performed for 10 seconds to 1 hour at the temperature in a range of the normal temperature to 800° C. under oxygen (O₂), nitrogen (N₂), argon (Ar), or hydrogen (H₂) atmosphere.

The n-electrode pad 170 may have a stack structure including refractory metals, such as titanium (Ti), aluminum (Al), gold (Au) and tungsten (W) which are sequentially stacked.

The p-electrode pad 160 may have a stack structure including refractory metals, such as titanium (Ti), aluminum (Al), gold (Au) and tungsten (W) which are sequentially stacked.

FIGS. 57 and 58 are sectional views showing an AlN-based supporting substrate layer formed on a III-nitride-based sacrificial layer or on a nitride-based thin film layer including a stacked structure of a nitride-based sacrificial layer and a nitride-based flattening layer formed on an upper portion of a sapphire substrate, which is an insulating growth substrate, according to a twentieth embodiment of the present invention.

In detail, referring to FIG. 57, a sacrificial layer 20′, which is grown into a III-nitride-based semiconductor under the temperature below 800° C., is formed on a sapphire substrate 10′. In addition, a supporting substrate layer 30′ including AlN-based materials is deposited on the sacrificial layer 20′. FIG. 58 is slightly different from FIG. 57 in that a flattening layer 40′ which is grown into a III-nitride-based semiconductor under the temperature of 800° C. or above, is formed on the sacrificial layer 20′ before the supporting substrate layer 30′ including AlN-based materials is deposited on the sacrificial layer 20′, in order to improve quality of the thin film layer including AlN-based materials.

The sacrificial layer 20′ formed under the low temperature condition absorbs laser beams having strong energy irradiated through a rear surface of the sapphire substrate 10′ and facilitates the release of the sapphire growth substrate using heat obtained from the laser beam. When the sapphire substrate 10′ is separated by means of the laser beam, the supporting substrate layer 30′ including the AlN-based materials prevents the nitride-based thick film layer formed on the supporting substrate layer 30′ or the thin film layer of the light emitting structure from being thermally and mechanically deformed or decomposed.

The supporting substrate layer 30′ including the AlN-based materials has chemical formula of AlxGa1-xN (x is 50% or more), and is prepared in the form of a single layer or a bi-layer. Preferably, the supporting substrate layer 30′ includes a thick AlN single layer.

The supporting substrate layer 30′ including the AlN-based materials is preferably deposited through the MOCVD or hybrid vapor phase epitaxy (HVPE) to improve quality of the thin film layer. However, the supporting substrate layer 30′ can also be deposited through ALD, PLD, sputtering using plasma having a strong energy source, or physical and chemical deposition.

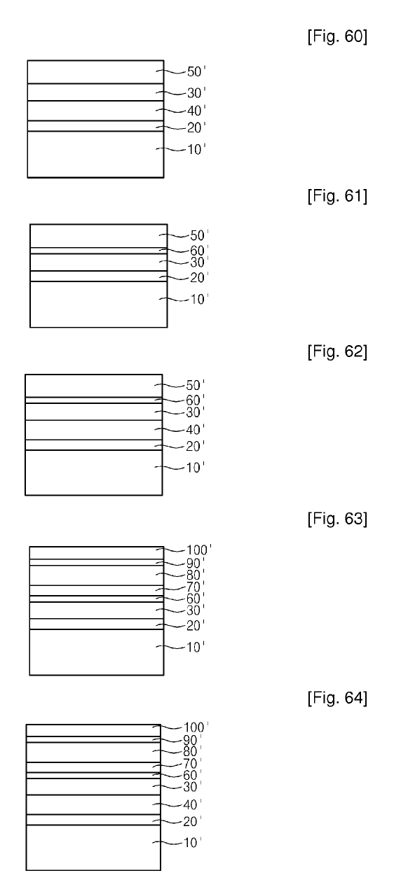

FIGS. 59 and 60 are sectional views showing a nitride-based thick film layer for a high-quality growth substrate, which is grown at the temperature of 800° C. or above on an upper portion of a structure where a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-first embodiment of the present invention.

In detail, FIGS. 59 and 60 show structures designed to fabricate a thick film layer 50′ for a new substrate used to grow a homo-epitaxial III-nitride-based semiconductor thin film on the AlN-based supporting substrate layer 30′ formed in the twentieth embodiment of the present invention.

The thick film layer 50′ may provide a high-quality nitride-based substrate required for optoelectronic devices, such as high-quality LEDs and LDs, and various transistors. To this end, the HVPE method or the MOCVD method exhibiting a relatively high growth rate is primarily applied when forming the thick film layer 50′. However, the PLD method or the sputtering method can also be used.

FIGS. 61 and 62 are sectional views showing a nitride-based thin nucleation layer grown at the temperature less than 800° C., and a nitride-based thick film layer grown at the temperature of 800° C. or above to provide a thick layer for a high-quality growth substrate, in which the nitride-based thin nucleation layer and the nitride-based thick film layer are sequentially formed on an upper portion of a structure where a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-second embodiment of the present invention.

In detail, FIGS. 61 and 62 are substantially identical to FIGS. 59 and 60, except for a new nucleation layer 60′, which is formed under the temperature of 800° C. or below before the thick film layer 50′ used to grow the homo-epitaxial III-nitride-based semiconductor thin film is formed on the supporting substrate layer 30′.

The initial sapphire substrate is removed from the template shown in FIGS. 59 to 62 by irradiating laser beams having storing energy, thereby providing a substrate suitable for various high-quality optoelectronic devices, such as nitride-based LD, LED, HBT, HFET, HEMT, MESFET and MOSFET.

FIGS. 63 and 64 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-third embodiment of the present invention.

In detail, the LED stack structure including II-nitride-based semiconductors formed on the AlN-based supporting substrate layer 30′ basically includes four layers of an undoped buffering nitride-based layer 70′ serving as a buffer layer, an n-type nitride-based cladding layer 80′, a multi-quantum well nitride-based active layer 90′, and a p-type nitride-based cladding layer 100′. A nucleation layer 60′ formed under the temperature less than 800° C. can be interposed between the AlN-based supporting substrate layer 30′ and the undoped buffering nitride-based layer 70′, or not.

In more detail, each of the undoped buffering nitride-based layer 70′ serving as a buffer layer, the n-type nitride-based cladding layer 80′, the multi-quantum well nitride-based active layer 90′, and the p-type nitride-based cladding layer 100′ basically includes one selected from compounds expressed as AlxInyGazN (x, y, and z are integers) which is a general formula of III-nitride-based compound. Dopants are added to the n-type nitride-based cladding layer 80′ and the p-type nitride-based cladding layer 100′.

In addition, the nitride-based active layer 90′ can be prepared in the form of a single layer, a multi-quantum well (MQW) structure, or multi-quantum dots or wires.

For instance, if GaN-based compound is employed, the n-type nitride-based cladding layer 80′ includes GaN and n-type dopants added to GaN, such as Si, Ge, Se, Te, etc., and the nitride-based active layer 90′ has an InGaN/GaN MQW structure or an AlGaN/GaN MQW structure. In addition, the p-type nitride-based cladding layer 100 includes GaN and p-type dopants such as Mg, Zn, Ca, Sr, Ba, Be, etc. added to GaN.

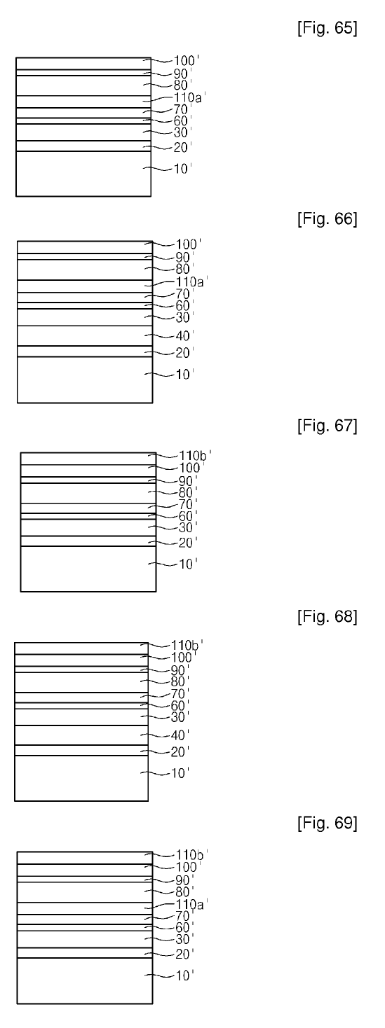

FIGS. 65 and 66 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-fourth embodiment of the present invention.

In detail, FIGS. 65 and 66 show the nitride-based LED structure similar to that of the twenty-third embodiment, but a first tunnel junction layer 110a′ is interposed between the undoped buffering nitride-based layer 70′ serving as a buffer layer and the n-type nitride-based cladding layer 80′. The first tunnel junction layer 110a′ positioned below the n-type nitride-based cladding layer 80′ facilitates fabrication of a high-quality n-type ohmic contact layer required for the high-quality nitride-based light emitting device. In addition, the first tunnel junction layer 110a′ allows light generated from the nitride-based active layer 90′ to be discharged to the exterior as much as possible.

The first tunnel junction layer 110a′ basically includes one selected from compounds expressed as AlaInbGacNxPyAsz (a, b, c, x, y and z are integers) consisting of III-V group elements. The first tunnel junction layer 110a′ can be prepared in the form of a single layer having a thickness of 50 nm or less. Preferably, the first tunnel junction layer 110a′ is prepared in the form of a bi-layer, a tri-layer or a multi-layer.

Preferably, the first tunnel junction layer 110a′ has a super-lattice structure. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the first tunnel junction layer 110a′ may include an epitaxial layer, a poly-crystal layer or an amorphous layer having II-group elements (Mg, Be, Zn) or IV-group elements (Si, Ge) added thereto.

FIGS. 67 and 68 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-fifth embodiment of the present invention.

In detail, FIGS. 67 and 68 show the nitride-based LED structure similar to that of the twenty-third embodiment, but a second tunnel junction layer 110b′ is provided on the p-type nitride-based cladding layer 100′. The second tunnel junction layer 110b′ positioned on the p-type nitride-based cladding layer 100′ facilitates fabrication of a high-quality p-type ohmic contact layer required for the high-quality nitride-based light emitting device. In addition, the second tunnel junction layer 110b′ allows light generated from the nitride-based active layer 90′ to be discharged to the exterior as much as possible.

The second tunnel junction layer 110b′ basically includes one selected from compounds expressed as AlaInbGacNxPyAsz (a, b, c, x, y and z are integers) consisting of III-V group elements. The second tunnel junction layer 110b′ can be prepared in the form of a single layer having a thickness of 50 nm or less. Preferably, the second tunnel junction layer 110b′ is prepared in the form of a bi-layer, a tri-layer or a multi-layer.

Preferably, the second tunnel junction layer 110b′ has a super-lattice structure. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the second tunnel junction layer 110b′ may include an epitaxial layer, a poly-crystal layer or an amorphous layer having III-group elements (Mg, Be, Zn) or IV-group elements (Si, Ge) added thereto.

FIGS. 69 and 70 are sectional views showing a light emitting diode (LED) stack structure having high quality and including a III-nitride-based semiconductor, in which the light emitting diode (LED) stack structure is formed on an upper portion of a sapphire substrate, which is an initial insulating growth substrate and on which a III-nitride-based sacrificial layer or a nitride-based thin film layer including a stacked structure of a nitride-based sacrificial layer and a nitride-based flattening layer, and an AlN-based supporting substrate layer are sequentially formed according to a twenty-sixth embodiment of the present invention.

In detail, FIGS. 69 and 70 show the nitride-based LED structure similar to that of the twenty-third embodiment, but a first tunnel junction layer 110a′ is interposed between the undoped buffering nitride-based layer 70′ serving as a buffer layer and the n-type nitride-based cladding layer 80′, and a second tunnel junction layer 110b′ is provided on the p-type nitride-based cladding layer 100′. The first and second tunnel junction layer 110a′ and 110b′, which are positioned at a lower portion of the n-type nitride-based cladding layer 80′ and at an upper portion of the p-type nitride-based cladding layer 100′, respectively, facilitate fabrication of a high-quality n-type ohmic contact layer required for the high-quality nitride-based light emitting device. In addition, the first and second tunnel junction layers 110a′ and 110b′ allow light generated from the nitride-based active layer 90′ to be discharged to the exterior as much as possible.

The first and second tunnel junction layers 110a′ and 110b′ basically include one selected from compounds expressed as AlaInbGacNxPyAsz (a, b, c, x, y and z are integers) consisting of III-V group elements. The first and second tunnel junction layers 110a′ and 110b′ can be prepared in the form of a single layer having a thickness of 50 nm or less. Preferably, the first and second tunnel junction layers 110a′ and 110b′ are prepared in the form of a bi-layer, a tri-layer or a multi-layer.

Preferably, the first and second tunnel junction layers 110a′ and 110b′ have a super-lattice structure. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the first tunnel junction layer 110a′ may include an epitaxial layer, a poly-crystal layer or an amorphous layer having II-group elements (Mg, Be, Zn) or IV-group elements (Si, Ge) added thereto.

FIG. 71 is a process flowchart showing the manufacturing process of a high-quality p-side down light emitting diode according to a twenty-seventh embodiment of the present invention, in which the high-quality p-side down light emitting diode is manufactured by using the LED stack structures according to the twenty-third to twenty-sixth embodiments of the present invention in such a manner that a p-type nitride cladding layer can be located below an n-type nitride cladding layer.

In detail, FIG. 71 shows a process of forming a high-quality nitride-based LED by using the template of the high-quality supporting substrate layer 30′ including AlN-based materials according to twentieth to twenty-second embodiments of the present invention. First, the high-quality supporting substrate layer 30′ including AlN-based materials is grown and then the high-quality nitride-based light emitting structure is grown (step \textcircled{1}).

In order to minimize dislocation density and cracks, which are generated in the process of growing the nitride-based light emitting structure, the surface treatment, the dry etching, or the lateral epitaxial overgrowth (LEO) scheme using amorphous silicon oxide SiO or amorphous nitride SiNx can be performed before the layers from the undoped buffering nitride-based layer 70′ serving as a buffer layer to the p-type nitride-based cladding layer 100′ have been deposited. Then, after growing the high-quality nitride-based light emitting structure, the p-type highly reflective ohmic electrode is formed (step \textcircled{2}).

Before the p-type highly reflective ohmic electrode is formed, the litho-process, the patterning process, the etching process, and the surface roughening process can be performed relative to the upper surface of the p-type nitride cladding layer or the second tunnel junction layer. In particular, if the tunnel junction layer is stacked on the p-type nitride cladding layer, an Al-related high reflective metal can be directly used for the highly-reflective p-type ohmic electrode. After forming the highly-reflective p-type ohmic electrode, a thick film for a heat sink is formed through the typical bonding transfer and electroplating processes (step \textcircled{3}).

Then, the laser beam having strong energy is irradiated through a rear surface of the transparent sapphire substrate 10, so that the sacrificial layer 20′ including III-nitride-based semiconductors and being formed on the sapphire substrate 10 absorbs the laser beam while generating heat having the temperature about 1000° C. Thus, the nitride-based semiconductor materials are thermo-chemically decomposed, thereby removing the sapphire substrate, which is the initial insulating growth substrate (step \textcircled{4}).

After that, the lithography and etching processes are performed to completely remove the supporting substrate layer including the AlN-based materials, which are semi-insulating or insulating materials (step \textcircled{5}). Then, the highly-transparent n-type ohmic contact layer and the n-type electrode pad are formed (step \textcircled{6}). Before the highly-transparent n-type ohmic contact layer is formed, the surface roughening process and the surface patterning process can be performed in order to discharge the light generated from the active layer to the exterior as much as possible.

FIGS. 72 to 75 are sectional views showing a high-quality p-side down light emitting diode according to a twenty-eighth embodiment of the present invention, in which the high-quality p-side down light emitting diode is manufactured according to the flowchart shown in FIG. 71 by using the LED stack structures according to the twenty-third embodiment of the present invention.

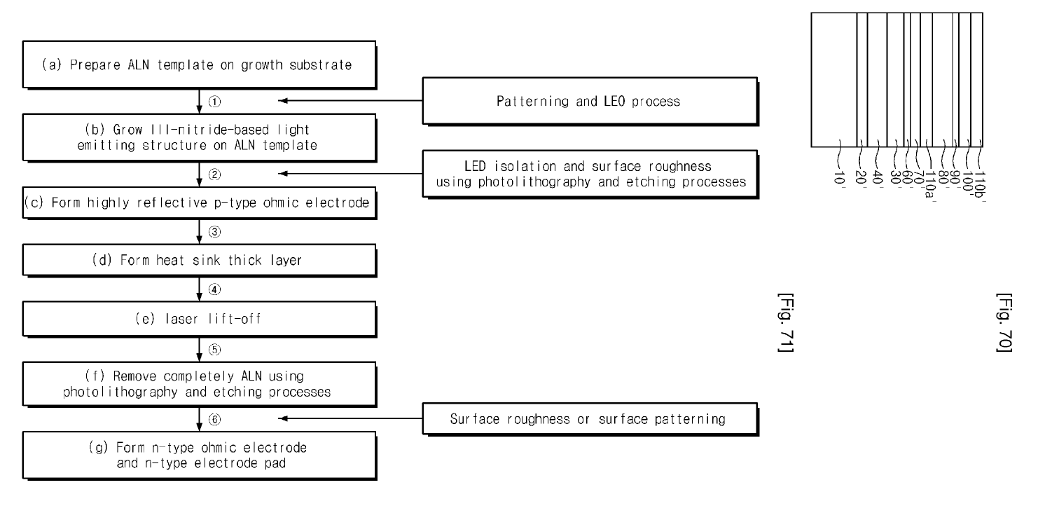

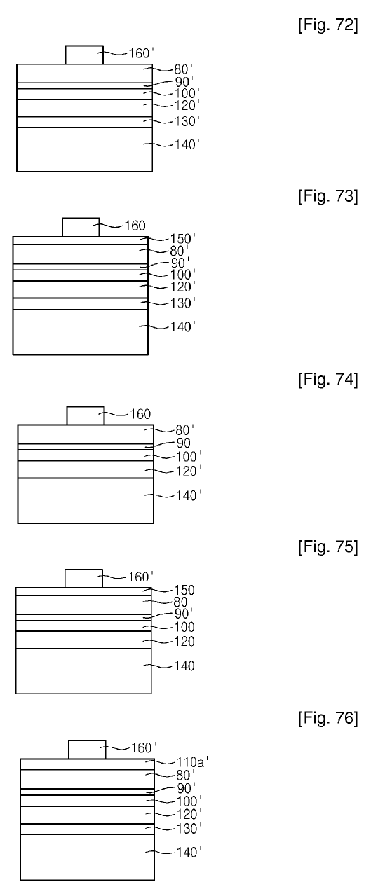

In detail, if the bonding transfer process is employed, a bonding layer 130′ is necessary to bond the heat sink plate to a highly reflective p-type ohmic electrode layer 120′. The bonding material layer 130′ preferably includes metals having higher cohesion properties and low melting points, such as indium (In), tin (Sn), zinc (Zn), silver (Ag), palladium (Pd), or gold (Au), and alloys or solid solution of the above metals. However, if the electroplating process is employed, such a bonding layer 130′ is not necessary. According to the present invention, the electroplating process, which is an electrochemical process, is primarily applied instead of the bonding transfer process. FIGS. 72 and 73 show the structure to which the bonding transfer process is applied, and FIGS. 74 and 75 show the structure to which the electroplating process is applied.

In general, the n-type nitride-based cladding layer has low sheet resistance, so the highly transparent n-type ohmic electrode layer is not necessary. However, in order to fabricate the high-quality light emitting device having higher reliability, the highly transparent n-type ohmic electrode layer is necessary. Accordingly, the highly transparent n-type ohmic electrode layer is primarily formed. At the same time, the surface roughening process and the patterning process can be employed in order to maximize the external quantum efficiency.

FIGS. 76 to 79 are sectional views showing a high-quality p-side down light emitting diode according to a twenty-ninth embodiment of the present invention, in which the high-quality p-side down light emitting diode is manufactured according to the flowchart shown in FIG. 71 by using the LED stack structures according to the twenty-fourth embodiment of the present invention.

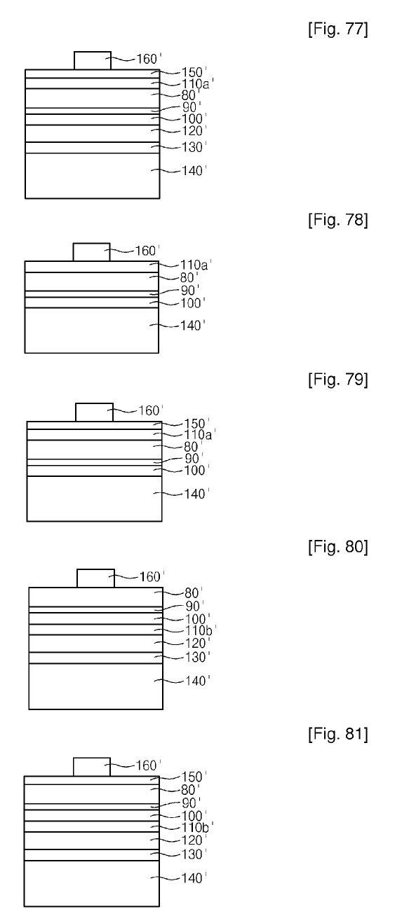

In detail, the LED according to the twenty-ninth embodiment of the present invention is similar to that of the twenty-eighth embodiment of the present invention, but the first tunnel junction layer 110a′ is introduced onto the n-type nitride-based cladding layer 80′. FIGS. 76 and 77 show the structure to which the bonding transfer process is applied, and FIGS. 78 and 79 show the structure to which the electroplating process is applied.

FIGS. 80 to 83 are sectional views showing a high-quality p-side down light emitting diode according to a thirtieth embodiment of the present invention, in which the high-quality p-side down light emitting diode is manufactured according to the flowchart shown in FIG. 71 by using the LED stack structures according to the twenty-fifth embodiment of the present invention.

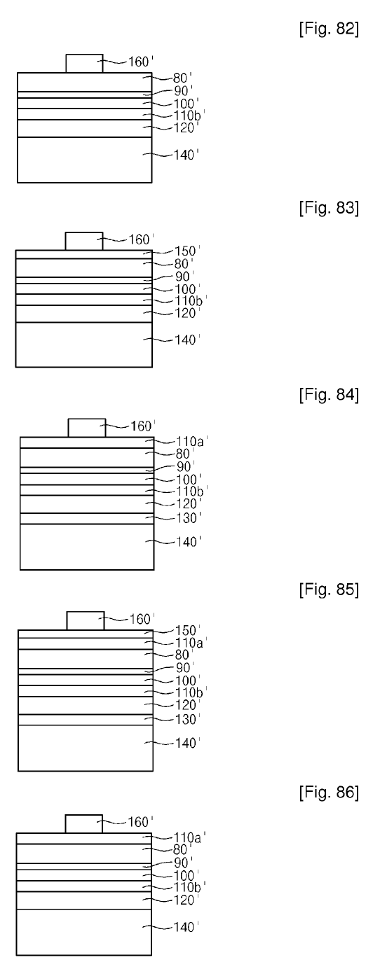

In detail, the LED according to the thirteenth embodiment of the present invention is similar to that of the twenty-eighth embodiment of the present invention, but the second tunnel junction layer 110b′ is introduced at a lower portion of the p-type nitride-based cladding layer 100′. FIGS. 80 and 81 show the structure to which the bonding transfer process is applied, and FIGS. 82 and 83 show the structure to which the electroplating process is applied.

FIGS. 84 to 87 are sectional views showing a high-quality p-side down light emitting diode according to a thirtieth-first embodiment of the present invention, in which the high-quality p-side down light emitting diode is manufactured according to the flowchart shown in FIG. 71 by using the LED stack structures according to the twenty-sixth embodiment of the present invention.

In detail, the LED according to the thirtieth-first embodiment of the present invention is similar to that of the twenty-eighth embodiment of the present invention, but the first and second tunnel junction layers 110a′ and 110b′ are introduced at an upper portion of the n-type nitride-based cladding layer 80′ and at a lower portion of the p-type nitride-based cladding layer 100′, respectively. FIGS. 84 and 85 show the structure to which the bonding transfer process is applied, and FIGS. 86 and 87 show the structure to which the electroplating process is applied.

FIG. 88 is a process flowchart showing the manufacturing process of a high-quality n-side down light emitting diode according to a thirtieth-second embodiment of the present invention, in which the high-quality n-side down light emitting diode is manufactured by using the LED stack structures according to the twenty-third to twenty-sixth embodiments of the present invention in such a manner that an n-type nitride cladding layer can be located below a p-type nitride cladding layer.

In detail, FIG. 88 shows a process of forming a high-quality nitride-based LED by using the template of the high-quality supporting substrate layer 30′ including AlN-based materials according to twentieth to twenty-second embodiments of the present invention. First, the high-quality supporting substrate layer 30′ including AlN-based materials is grown and then the high-quality nitride-based light emitting structure is grown (step \textcircled{1}).

In order to minimize dislocation density and cracks, which are generated in the process of growing the nitride-based light emitting structure, the surface treatment, the dry etching, or the lateral epitaxial overgrowth (LEO) scheme using amorphous silicon oxide SiO₂ or amorphous nitride SiNx can be performed before the layers from the undoped buffering nitride-based layer 70′ serving as a buffer layer to the p-type nitride-based cladding layer 100′ have been deposited. Then, after growing the high-quality nitride-based light emitting structure, a Si-substrate, a GaAs-substrate, a sapphire substrate or a temporal substrate is bonded to an upper portion of the p-type nitride-based cladding or the second tunnel junction layer by using bonding materials, such as wax which is an organic bonding material. Prior to the above procedure, the surface roughening and patterning processes can be performed relative to the upper portion of the p-type nitride-based cladding or the second tunnel junction layer. In addition, the temporal substrate can be attached to the upper portion of the p-type nitride-based cladding or the second tunnel junction layer after forming the highly transparent p-type ohmic electrode (step \textcircled{2}).

Then, the laser beam having strong energy is irradiated through a rear surface of the transparent sapphire substrate 10′, so that the sacrificial layer 20′ including III-nitride-based semiconductors and being formed on the sapphire substrate 10 absorbs the laser beam while generating heat having the temperature about 1000° C. Thus, the nitride-based semiconductor materials are thermo-chemically decomposed, thereby removing the sapphire substrate, which is the initial insulating growth substrate (step \textcircled{3}).

In addition, after removing the insulating sapphire substrate through the LLO scheme, the supporting substrate layer including the AlN-based materials, which are semi-insulating or insulating materials, is completed removed (step \textcircled{4}). Then, the highly-transparent n-type ohmic electrode is formed on the n-type nitride cladding layer or the first tunnel junction layer.

Before the highly-transparent n-type ohmic electrode is formed, the litho-process, the patterning process, the etching process, and the surface roughening process can be performed relative to the upper surface of the n-type nitride cladding layer or the first tunnel junction layer (step \textcircled{5}).

In particular, if the tunnel junction layer is stacked on the n-type nitride cladding layer, an Al-related high reflective metal can be directly used for the highly-reflective n-type ohmic electrode. After forming the highly-reflective n-type ohmic electrode, a thick film for a heat sink is formed through the typical bonding transfer and electroplating processes (step \textcircled{6}).

Then, the highly transparent p-type ohmic electrode and the p-type electrode pad are formed (step \textcircled{7}). Before the highly transparent p-type ohmic electrode, the surface roughening process, and the surface patterning process can be performed in order to discharge the light generated from the active layer to the exterior as much as possible. If the highly transparent p-type ohmic electrode has already been formed in step, the p-type electrode pad 180′ is only formed in step.

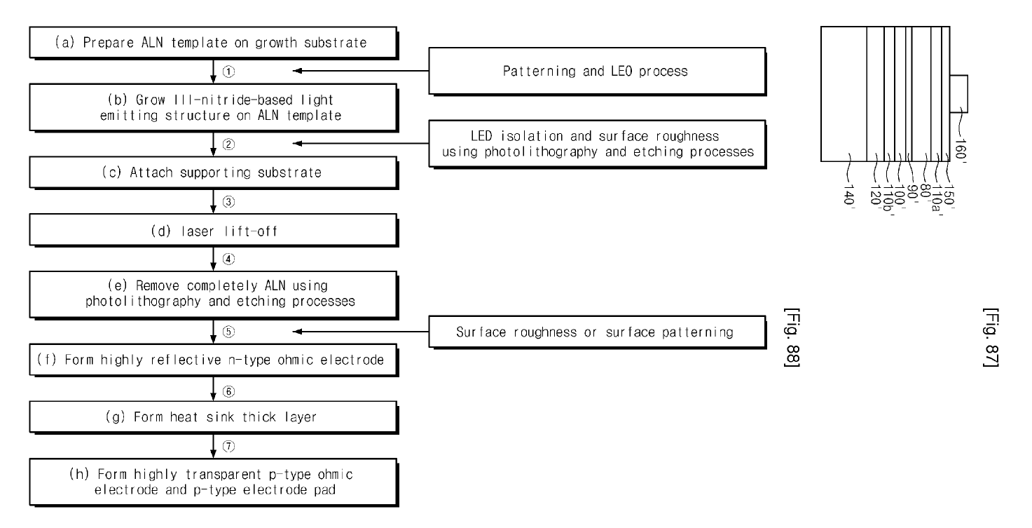

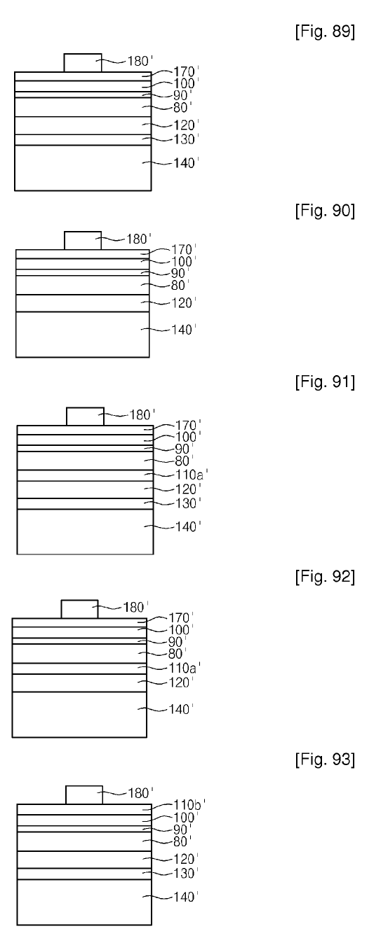

FIGS. 89 and 90 are sectional views showing a high-quality n-side down light emitting diode according to a thirtieth-third embodiment of the present invention, in which the high-quality n-side down light emitting diode is manufactured according to the flowchart shown in FIG. 88 by using the LED stack structures according to the twenty-third embodiment of the present invention.

Different from the p-side down LED, the p-type nitride-based cladding layer located at the uppermost portion of the LED has high sheet resistance, so the highly transparent ohmic electrode layer 170′ having high transmittance and capable of facilitating the lateral current spreading and the vertical current injecting must be formed on the p-type nitride-based cladding layer.

FIGS. 91 and 92 are sectional views showing a high-quality n-side down light emitting diode according to a thirtieth-fourth embodiment of the present invention, in which the high-quality n-side down light emitting diode is manufactured according to the flowchart shown in FIG. 88 by using the LED stack structures according to the twenty-fourth embodiment of the present invention.

In detail, the LED according to the thirteen-fourth embodiment of the present invention is similar to that of the thirtieth-third embodiment of the present invention, but the first tunnel junction layer 110a′ is introduced at a lower portion of the n-type nitride-based cladding layer 80′. FIG. 91 shows the structure to which the bonding transfer process is applied, and FIG. 92 shows the structure to which the electroplating process is applied.

FIGS. 93 to 96 are sectional views showing a high-quality n-side down light emitting diode according to a thirtieth-fifth embodiment of the present invention, in which the high-quality n-side down light emitting diode is manufactured according to the flowchart shown in FIG. 88 by using the LED stack structures according to the twenty-fifth embodiment of the present invention.

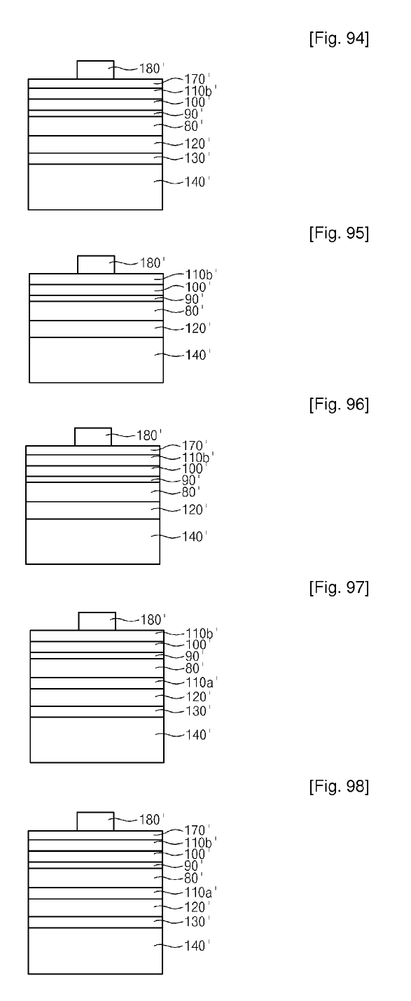

In detail, the LED according to the thirtieth-fifth embodiment of the present invention is similar to that of the thirtieth-third embodiment of the present invention, but the second tunnel junction layer 110b′ is introduced on the p-type nitride-based cladding layer 100′. FIGS. 93 and 94 show the structure to which the bonding transfer process is applied, and FIGS. 95 and 96 show the structure to which the electroplating process is applied.

FIGS. 97 to 100 are sectional views showing a high-quality n-side down light emitting diode according to a thirtieth-sixth embodiment of the present invention, in which the high-quality n-side down light emitting diode is manufactured according to the flowchart shown in FIG. 88 by using the LED stack structures according to the twenty-sixth embodiment of the present invention.

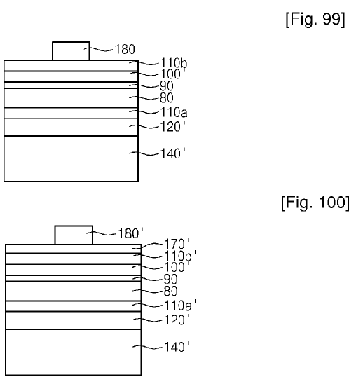

In detail, the LED according to the thirtieth-sixth embodiment of the present invention is similar to that of the thirtieth-third embodiment of the present invention, but the first and second tunnel junction layers 110a′ and 110b′ are introduced at lower and upper portions of the n-type and p-type nitride-based cladding layer 80′ and 100′, respectively. FIGS. 97 and 98 show the structure to which the bonding transfer process is applied, and FIGS. 99 and 100 show the structure to which the electroplating process is applied.

FIG. 101 is a process flowchart showing the manufacturing process of a high-quality n-side down light emitting diode according to a thirtieth-seventh embodiment of the present invention, in which the high-quality n-side down light emitting diode is manufactured by using the LED stack structures according to the twenty-third to twenty-sixth embodiments of the present invention in such a manner that an n-type nitride cladding layer can be located below a p-type nitride cladding layer.

In detail, FIG. 101 shows a process of forming a high-quality nitride-based LED by using the template of the high-quality supporting substrate layer 30′ including AlN-based materials according to twentieth to twenty-second embodiments of the present invention. First, the high-quality supporting substrate layer 30′ including AlN-based materials is grown and then the high-quality nitride-based light emitting structure is grown (step \textcircled{1}).

In order to minimize dislocation density and cracks, which are generated in the process of growing the nitride-based light emitting structure, the surface treatment, the dry etching, or the lateral epitaxial overgrowth (LEO) scheme using amorphous silicon oxide SiO₂ or amorphous nitride SiNx can be performed before the layers from the undoped buffering nitride-based layer 70′ serving as a buffer layer to the p-type nitride-based cladding layer 100′ have been deposited. Then, after growing the high-quality nitride-based light emitting structure, a Si-substrate, a GaAs-substrate, a sapphire substrate or a temporal substrate is bonded to an upper portion of the p-type nitride-based cladding or the second tunnel junction layer by using bonding materials, such as wax which is an organic bonding material. Prior to the above procedure, the surface roughening and patterning processes can be performed relative to the upper portion of the p-type nitride-based cladding or the second tunnel junction layer. In addition, the temporal substrate can be attached to the upper portion of the p-type nitride-based cladding or the second tunnel junction layer after forming the highly transparent p-type ohmic electrode (step \textcircled{2}).

Then, the laser beam having strong energy is irradiated through a rear surface of the transparent sapphire substrate 10′, so that the sacrificial layer 20′ including III-nitride-based semiconductors and being formed on the sapphire substrate 10 absorbs the laser beam while generating heat having the temperature about 1000° C. Thus, the nitride-based semiconductor materials are thermo-chemically decomposed, thereby removing the sapphire substrate, which is the initial insulating growth substrate (step \textcircled{3}).

In addition, after removing the insulating sapphire substrate through the LLO scheme, the supporting substrate layer including the AlN-based materials, which are semi-insulating or insulating materials, is partially removed through the lithography and etching processes (step \textcircled{4}). Then, the highly-reflective n-type ohmic electrode is formed on the n-type nitride cladding layer or the first tunnel junction layer. Before the highly-reflective n-type ohmic electrode is formed, the litho-process, the patterning process, the etching process, and the surface roughening process can be performed relative to the upper surface of the n-type nitride cladding layer or the first tunnel junction layer (step \textcircled{5}).

In particular, if the tunnel junction layer is stacked on the n-type nitride cladding layer, an Al-related high reflective metal can be directly used for the highly-reflective n-type ohmic electrode. After forming the highly-reflective n-type ohmic electrode, a thick film for a heat sink is formed through the typical bonding transfer and electroplating processes (step \textcircled{6}).

Then, the highly transparent p-type ohmic electrode and the p-type electrode pad are formed (step \textcircled{7}). Before the highly transparent p-type ohmic electrode, the surface roughening process, and the surface patterning process can be performed in order to discharge the light generated from the active layer to the exterior as much as possible. If the highly transparent p-type ohmic electrode has already been formed in step \textcircled{2}, the p-type electrode pad 180′ is only formed.

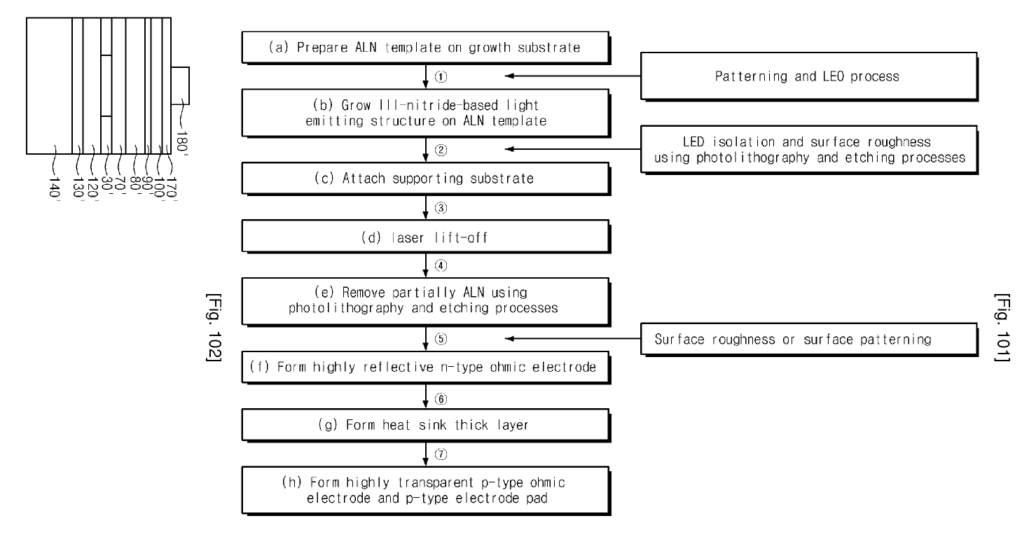

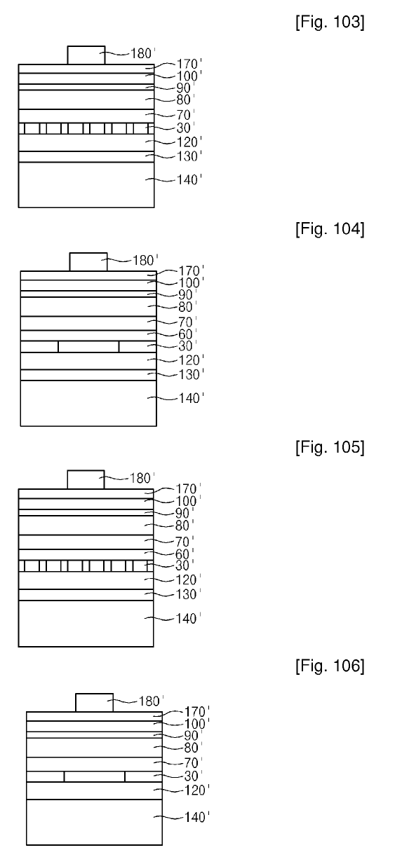

FIGS. 102 to 105 are sectional views showing a high-quality n-side down light emitting diode according to a thirtieth-eighth embodiment of the present invention, in which the high-quality n-side down light emitting diode is manufactured through a bonding transfer scheme according to the flowchart shown in FIG. 101 by using the LED stack structures according to the twenty-third embodiment of the present invention. FIGS. 102 and 103 show the structure to which the bonding transfer process is applied, and FIGS. 104 and 105 show the structure to which the electroplating process is applied.

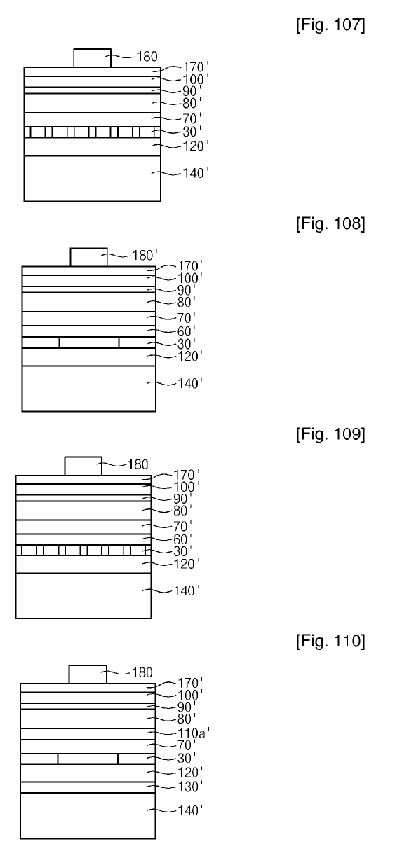

In addition, FIGS. 106 to 109 are sectional views showing a high-quality n-side down light emitting diode according to a thirtieth-ninth embodiment of the present invention, in which the high-quality n-side down light emitting diode is manufactured through an electroplating scheme according to the flowchart shown in FIG. 101 by using the LED stack structures according to the twenty-third embodiment of the present invention. FIGS. 106 and 107 show the structure to which the bonding transfer process is applied, and FIGS. 108 and 109 show the structure to which the electroplating process is applied.

Different from the p-side down LED, the p-type nitride-based cladding layer located at the uppermost portion of the LED has high sheet resistance, so the highly transparent ohmic electrode layer 170′ having high transmittance and capable of facilitating the lateral current spreading and the vertical current injecting must be formed on the p-type nitride-based cladding layer.

In detail, different from the thirtieth-third embodiment of the present invention, the supporting substrate layer 30′ including the AlN-base materials is not completely removed, but still supports the nitride-based light emitting structure at a predetermined interval, so the high quality nitride-based LED has structural stability. In addition, since the p-type ohmic electrode layer 120′ directly makes contact with the n-type nitride-based cladding layer 80′ through the supporting substrate layer 30′ including the AlN-base materials, the p-type ohmic electrode layer 120′ may serve as an electrode layer having superior current injecting and light reflecting characteristics.

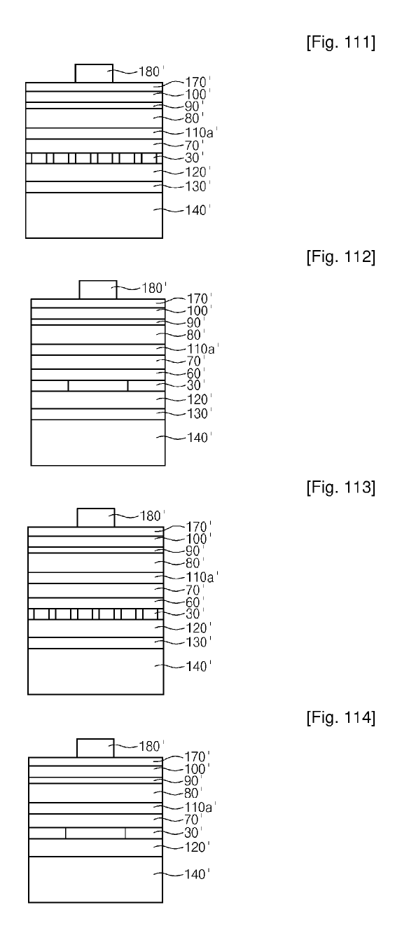

FIGS. 110 to 113 are sectional views showing a high-quality n-side down light emitting diode according to a fortieth embodiment of the present invention, in which the high-quality n-side down light emitting diode is manufactured through a bonding transfer scheme according to the flowchart shown in FIG. 101 by using the LED stack structures according to the twenty-fourth embodiment of the present invention. FIGS. 110 and 111 show the structure to which the bonding transfer process is applied, and FIGS. 112 and 113 show the structure to which the electroplating process is applied.

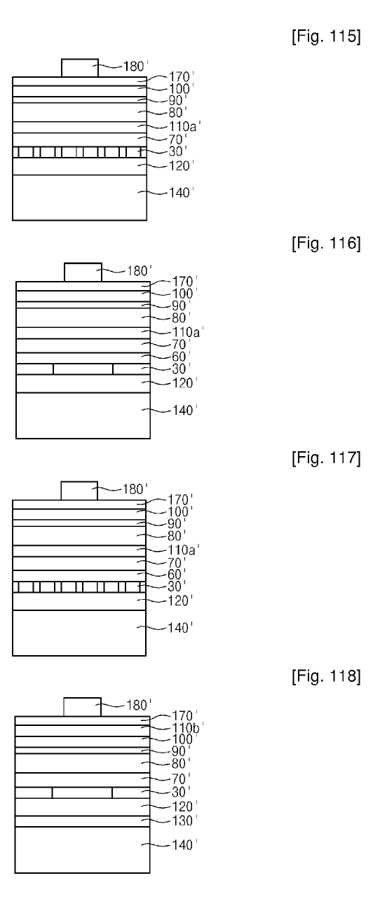

In addition, FIGS. 114 to 117 are sectional views showing a high-quality n-side down light emitting diode according to a fortieth-first embodiment of the present invention, in which the high-quality n-side down light emitting diode is manufactured through an electroplating scheme according to the flowchart shown in FIG. 101 by using the LED stack structures according to the twenty-fourth embodiment of the present invention. FIGS. 114 and 115 show the structure to which the bonding transfer process is applied, and FIGS. 116 and 117 show the structure to which the electroplating process is applied.

In detail, the LED according to the fortieth-first embodiment of the present invention is similar to that of the thirtieth-eighth and thirtieth-ninth embodiments of the present invention, but the first tunnel junction layer 110a′ is introduced at a lower portion of the n-type nitride-based cladding layer 80′.

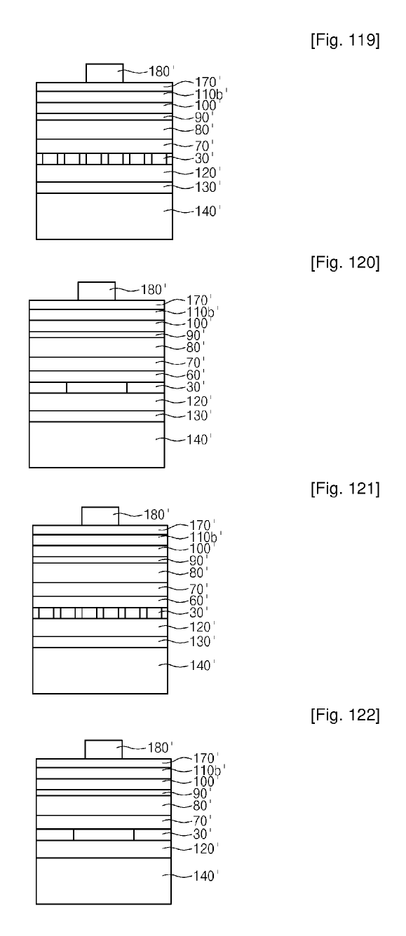

FIGS. 118 to 121 are sectional views showing a high-quality n-side down light emitting diode according to a fortieth-second embodiment of the present invention, in which the high-quality n-side down light emitting diode is manufactured through a bonding transfer scheme according to the flowchart shown in FIG. 101 by using the LED stack structures according to the twenty-fifth embodiment of the present invention. FIGS. 118 and 119 show the structure to which the bonding transfer process is applied, and FIGS. 120 and 121 show the structure to which the electroplating process is applied.

In addition, FIGS. 122 to 125 are sectional views showing a high-quality n-side down light emitting diode according to a fortieth-third embodiment of the present invention, in which the high-quality n-side down light emitting diode is manufactured through an electroplating scheme according to the flowchart shown in FIG. 101 by using the LED stack structures according to the twenty-fifth embodiment of the present invention.

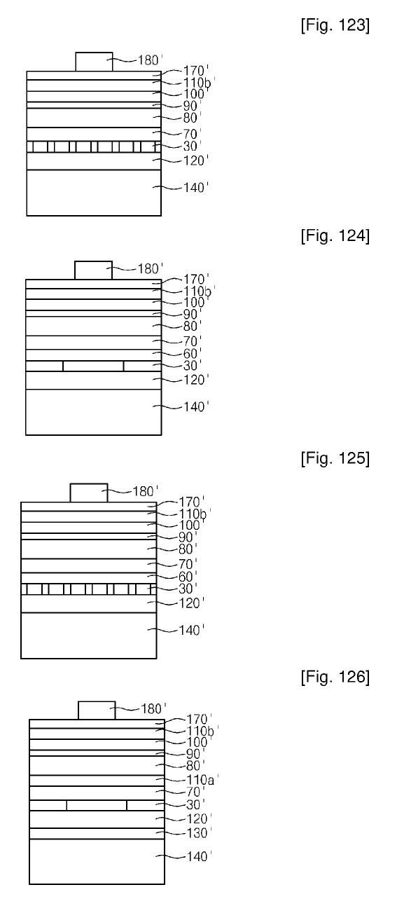

FIGS. 122 and 123 show the structure to which the bonding transfer process is applied, and FIGS. 124 and 125 show the structure to which the electroplating process is applied.

In detail, the LED according to the fortieth-third embodiment of the present invention is similar to that of the thirtieth-eighth and thirtieth-ninth embodiments of the present invention, but the second tunnel junction layer 110b′ is introduced on the p-type nitride-based cladding layer 100′.

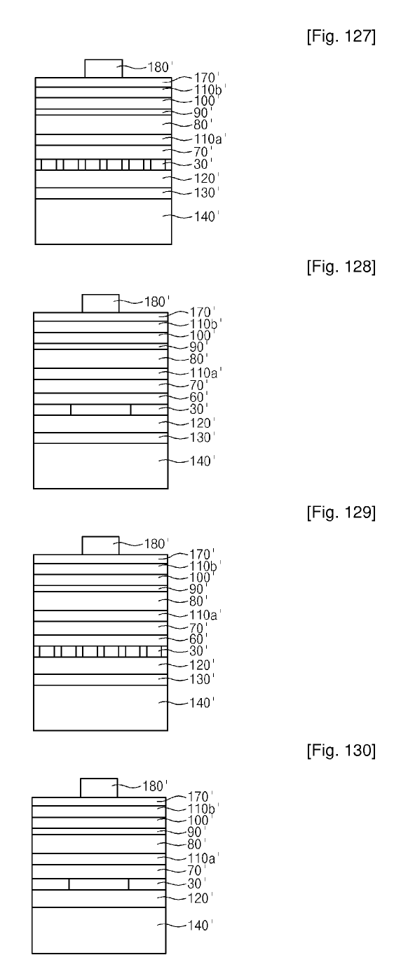

FIGS. 126 to 129 are sectional views showing a high-quality n-side down light emitting diode according to a fortieth-fourth embodiment of the present invention, in which the high-quality n-side down light emitting diode is manufactured through a bonding transfer scheme according to the flowchart shown in FIG. 101 by using the LED stack structures according to the twenty-sixth embodiment of the present invention. FIGS. 126 and 127 show the structure to which the bonding transfer process is applied, and FIGS. 128 and 129 show the structure to which the electroplating process is applied.

In addition, FIGS. 130 to 133 are sectional views showing a high-quality n-side down light emitting diode according to a fortieth-fifth embodiment of the present invention, in which the high-quality n-side down light emitting diode is manufactured through an electroplating scheme according to the flowchart shown in FIG. 101 by using the LED stack structures according to the twenty-sixth embodiment of the present invention.

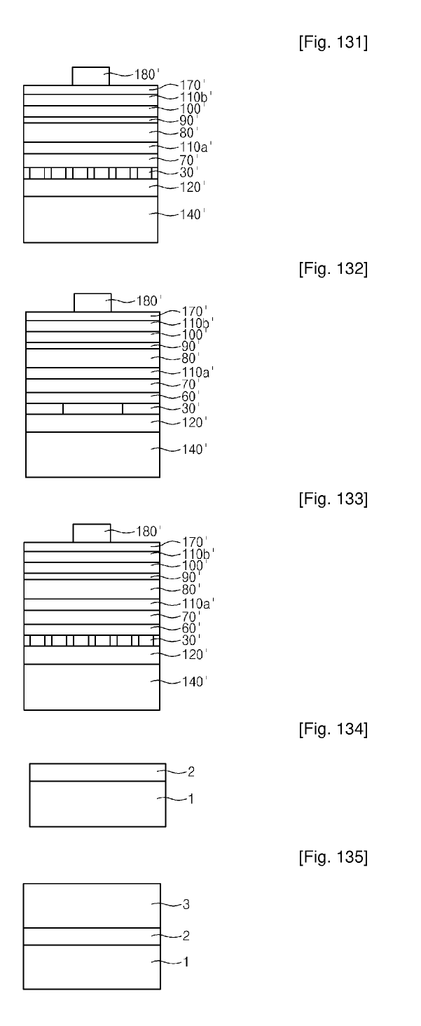

FIGS. 130 and 131 show the structure to which the bonding transfer process is applied, and FIGS. 132 and 133 show the structure to which the electroplating process is applied.

In detail, the LED according to the fortieth-fifth embodiment of the present invention is similar to that of the thirtieth-eighth and thirtieth-ninth embodiments of the present invention, but the first and second tunnel junction layers 110a′ and 110b′ are introduced on lower and upper portions of the n-type and p-type nitride-based cladding layers 80′ and 100′.

The subject matter of the present invention can be summarized as follows.

The supporting substrate layer 30′ including AlN-based materials is stacked/grown on the semiconductor thin layer. The semiconductor thin layer consists of the nitride-based flattening layer 20′ or the nitride-based flattening layer 20′ and the sacrificial layer 20′ including III-nitride-based semiconductors, and is formed on the insulating sapphire substrate 10′. Such a supporting substrate layer 30′ including the AlN-based materials attenuate stress derived from thermal and mechanical deformation when removing the sapphire substrate 10′ through the LLO scheme, thereby preventing the nitride-based thin film layer or the light emitting structure grown on the supporting substrate layer 30′ from being thermally and mechanically deformed or decomposed. The supporting substrate layer 30′ including the AlN-based materials is prepared in the form of a single layer or a bi-layer. Preferably, an single crystal material layer having a hexagonal system or a cubic system is primarily employed.

Meanwhile, before the supporting substrate layer 30′ including the AlN-based materials is stacked/grown on the flattening layer 20′ including III-nitride-based semiconductors, if amorphous silicon oxide SiO2 or amorphous nitride SiNx is formed on the flattening layer 20′ in the shape of an island through the patterning and etching processes, the nitride-based light emitting structure having a low dislocation density can be grown on the supporting substrate layer 30′.

In addition, preferably, the supporting substrate layer 30′ including the AlN-based materials is deposited at a thickness of 10 or less by means of chemical vapor deposition (CVD), such as metal organic chemical vapor deposition (MOCVD), hybrid vapor phase epitaxy deposition (HVPED), or atomic layer deposition (ALD), sputtering deposition using gas ions having high energy, or physical vapor deposition (PVD), such as pulsed laser deposition (PLD) using a laser energy source.

As mentioned above, the heat sink, which emits heat and protects the light emitting structure for the nitride-based light emitting device of the present invention, preferably includes metals, alloys or solid solution having superior electric and thermal conductivity. More preferably, instead of using silicon (Si) or a silicon substrate, the heat sink includes silicide that is an intermetallic compound, aluminum (Al), Al-related alloy or solid solution, copper (Cu), Cu-related alloy or solid solution, silver (Ag), Ag-related alloy or solid solution, tungsten (W), W-related alloy or solid solution, nickel (Ni), or Ni-related alloy or solid solution.

The present invention adopts the LLO scheme so as to remove the nitride-based light emitting structure from the insulating sapphire substrate 100. According to the present invention, the LLO scheme is not performed under the normal temperature and normal pressure and is performed in a state in which the sapphire substrate is immersed in acid solution such as HCl or base solution having the temperature of 40 or more degrees, in order to improve the product yield which may be lowered if crack of the nitride-based light emitting structure occurs during the process.

The bonding material layer 130′ preferably includes metals having higher cohesion properties and low melting points, such as indium (In), tin (Sn), zinc (Zn), silver (Ag), palladium (Pd), or gold (Au), and alloys or solid solution of the above metals.

The highly reflective p-type ohmic contact layer 120′ may include a thick layer of Ag and Rh without using Al and Al-related alloy or solid solution, which is a high reflective material that represents low specific contact resistance and high light reflectance on the p-nitride-based cladding layer 100′ or the second tunnel junction layer 110b′. In addition, the p-reflective ohmic contact layer 120′ may include a dual reflective layer or a triple reflective layer including the high reflective metal combined with nickel (Ni), palladium (Pd), platinum (Pt), zinc (Zn), magnesium (Mg), or gold (Au). Further, the p-reflective ohmic contact layer 430b may include a combination of transparent conductive oxide (TCO), transitional metal-based transparent conductive nitride, and the high reflective metal.

Each of the undoped buffering nitride-based layer 70′ serving as a buffer layer, the n-type nitride-based cladding layer 80′, the multi-quantum well nitride-based active layer 90′, and the p-type nitride-based cladding layer 100′ basically includes one selected from compounds expressed as AlxInyGazN (x, y, and z are integers) which is a general formula of III-nitride-based compound. Dopants are added to the n-type nitride-based cladding layer 80′ and the p-type nitride-based cladding layer 100′.

In addition, the n-type nitride-based active layer 90′ can be prepared in the form of a single layer, a multi-quantum well (MQW) structure, or multi-quantum dots or wires.

For instance, if GaN-based compound is employed, the n-type nitride-based cladding layer 80′ includes GaN and n-type dopants added to GaN, such as Si, Ge, Se, Te, etc., and the nitride-based active layer 90′ has an InGaN/GaN MQW structure or an AlGaN/GaN MQW structure. In addition, the p-type nitride-based cladding layer 100′ includes GaN and p-type dopants added to GaN, such as Mg, Zn, Ca, Sr, Ba, Be, etc.

The first and second tunnel junction layers 110a′ and 110b′ basically include one selected from compounds expressed as AlaInbGacNxPyAsz (a, b, c, x, y and z are integers) consisting of III-V group elements. The first and second tunnel junction layers 110a′ and 110b′ can be prepared in the form of a single layer having a thickness of 50 nm or less. Preferably, the first and second tunnel junction layers 110a′ and 110b′ are prepared in the form of a bi-layer, a tri-layer or a multi-layer.

Preferably, the first and second tunnel junction layers 110a′ and 110b′ have super-lattice structures. For instance, 30 or less pairs of elements can be repeatedly stacked in the form of a thin stack structure by using III-V group elements, such as InGaN/GaN, AlGaN/GaN, AlInN/GaN, AlGaN/InGaN, AlInN/InGaN, AlN/GaN, or AlGaAs/InGaAs.

More preferably, the first and second tunnel junction layers 110a′ and 110b′ may include a single-crystal layer, a poly-crystal layer or an amorphous layer having II-group elements (Mg, Be, Zn) or IV-group elements (Si, Ge) added thereto.

The high transparent ohmic electrode layers 150′ and 170′ stacked on the n-type and p-type nitride-based cladding layers 80′ and 100′ include oxide or transitional metal-based nitride. In particular, transparent conducive oxide (TCO) includes oxygen (O) combined with at least one selected from the group consisting of indium (In), tin (Sn), zinc (Zn), gallium (Ga), cadmium (Cd), magnesium (Mg), beryllium (Be), silver (Ag), molybdenum (Mo), vanadium (V), copper (Cu), iridium (Ir), rhodium (Rh), ruthenium (Ru), tungsten (W), titanium (Ti), tantalum (Ta), cobalt (Co), nickel (Ni), manganese (Mn), platinum (Pt), palladium (Pd), aluminum (Al), and lanthanoids (La).

In addition, transitional metal-based nitride includes nitrogen (N) combined with titanium (Ti), tungsten (W), tantalum (Ta), vanadium (V), chrome (Cr), zirconium (Zr), niobium (Nb), hafnium (Hf), rhenium (Re) or molybdenum (Mo).

The high transparent ohmic electrode layers 150′ and 170′ stacked on the n-type and p-type nitride-based cladding layers 80′ and 100′ include metal components that may form a new transparent conductive thin film in combination with the n-type and p-type nitride-based cladding layers 80′ and 100′ when it is subject to the heat treatment process at the oxygen atmosphere.

Preferably, the highly reflective n-type and p-type ohmic electrode layers 120′ formed on the bonding layer 130′ may include high reflective metals, such as aluminum (Al), silver (Ag), rhodium (Rh), nickel (Ni), palladium (Pd), and gold (Au), or alloys or solid solution of the above metals. In particular, according to the present invention, aluminum (Al) or Al-related alloy or solid solution is primarily used as a material for the highly reflective n-type and p-type ohmic electrode layers 120′ because aluminum (Al) represent thermal stability and superior reflectance at the wavelength band of 400 nm or less.

More preferably, the highly reflective n-type and p-type ohmic electrode layers 120′ may include the combination of the TCO, TCN and the high reflective metals.

In order to improve electrical and optical characteristics of the nitride-based light emitting device by providing a photonic crystal effect or by adjusting a roughness of an upper surface or a lower surface of the tunnel junction layers 110a′ and 110b′, a dot, a hole, a pyramid, a nano-rod, or a nano-columnar having a size of 10 nm or less can be provided through an interferometry scheme using interference of the laser beam and photo-reactive polymer or through an etching technology.

Another method of improving the electrical and optical characteristics of the nitride-based light emitting device through the surface roughness adjustment and photonic crystal effect has been suggested. This method is performed for 10 seconds to 1 hour at the temperature in a range of the normal temperature to 800° C. under oxygen (O₂), nitrogen (N₂), argon (Ar), or hydrogen (H₂) atmosphere.

The n-type and p-type electrode pads 160′ and 180′ may have a stack structure including refractory metals, such as titanium (Ti), aluminum (Al), gold (Au) and tungsten (W) which are sequentially stacked.

Hereinafter, a method of growing a high quality epitaxial layer to fabricate a semiconductor device according to embodiments of the present invention will be described. In the following description, the same elements that have been described in the previous embodiments may have the same function and structure if there are no special comments for them.

FIGS. 134 to 138 are sectional views showing the procedure of forming an epitaxial stack structure on a substrate for electronic and optoelectronic devices employing GaN-based semiconductors to provide a high quality epitaxial substrate according to a fortieth-sixth embodiment of the present invention.

Referring to FIGS. 134 to 138, a first epitaxial layer 2 is grown on the sapphire substrate which is an initial growth substrate 1 (see, FIG. 134). The first epitaxial layer 2 has a multi-layered stacking structure.

The first epitaxial layer 2 includes materials having a single crystalline structure, such as GaN, AlN, InN, AlGaN, InGaN, AlInN, InAlGaN, SiC, or SiCN, which is expressed as chemical formula InxAlyGazN (x, y and z are integers) or SixCyNz (x, y and z are integers). In addition, the first epitaxial layer 2 is deposited in the form of a single layer having a thickness of 30 nm or more. Preferably, the first epitaxial layer 2 is prepared in the form of a bi-layer or a multi-layer.

The first epitaxial layer 2 formed on the growth substrate 1 may have a multi-structure corresponding to InxAlyGazN (x, y and z are integers) or SixCyNz (x, y and z are integers).

IV-elements (Si, Ge, Te, Se), which are n-type dopant, and III-elements (Mg, Zn, Be), which are p-type dopant, can be added to the first epitaxial layer 2 according to the type of the electronic and optoelectronic devices.

The first epitaxial layer 2 is preferably deposited through chemical vapor deposition (CVD), such as MOCVD, HVPE or ALD (atomic level deposition), or through physical vapor deposition, such as PLD (pulsed laser deposition) using a strong energy source, or MBE (molecular beam epitaxy).

Then, as shown in FIG. 134, a thick film layer 3 having a thickness of 30 nm or more is formed on the first epitaxial layer 2 provided on the growth substrate 1 (see, FIG. 135).

The thick film layer 3 can be formed by using materials having electrical conductivity or electrical insulating property. At this time, the thick film layer 3 is formed through electrochemical deposition, such as electroplating or electroless plating representing higher deposition rate, physical and chemical vapor deposition, such as LPCVD (low pressure CVD) or PECVD (plasma enhanced CVD), sputtering, PLD, screen printing, or fusion bonding using a metal foil.

The material of the thick film layer 3 having the thickness of 30 nm or more must have superior electrical and thermal conductivity without causing oxidation and reduction reaction under hydrogen (H) and ammonia (NH3) atmosphere and the high temperature condition of 1000° C. or more.

In detail, the thick film layer includes at least one selected from the group consisting of Si, Ge, SiGe, GaAs, GaN, AlN, AlGaN, InGaN, BN, BP, BAs, BSb, AlP, AlAs, Alsb, GaSb, InP, InAs, InSb, GaP, InP, InAs, InSb, In2S3, PbS, CdTe, CdSe, CdlxZnxTe, In2Se3, CuInSe2, Hgl-xCdxTe, Cu2S, ZnSe, ZnTe, ZnO, W, Mo, Ni, Nb, Ta, Pt, Cu, Al, Ag, Au, ZrB2, WB, MoB, MoC, WC, ZrC, Pd, Ru, Rh, Ir, Cr, Ti, Co, V, Re, Fe, Mn, RuO, IrO2, BeO, MgO, SiO2, SiN, TiN, ZrN, HfN, VN, NbN, TaN, MoN, ReN, CuI, Diamond, DLC (diamond like carbon), SiC, WC, TiW, TiC, CuW, or SiCN.

In addition, a single crystalline stack structure, a poly-crystalline stack structure, or an amorphous stack structure is prepared in the form of a single layer, a bi-layer or a tri-layer by using the material for the thick film layer 3. As a material for the thick film layer 3 having the thickness of 30 nm or more, alloys or solid solution of the above metals can be utilized.

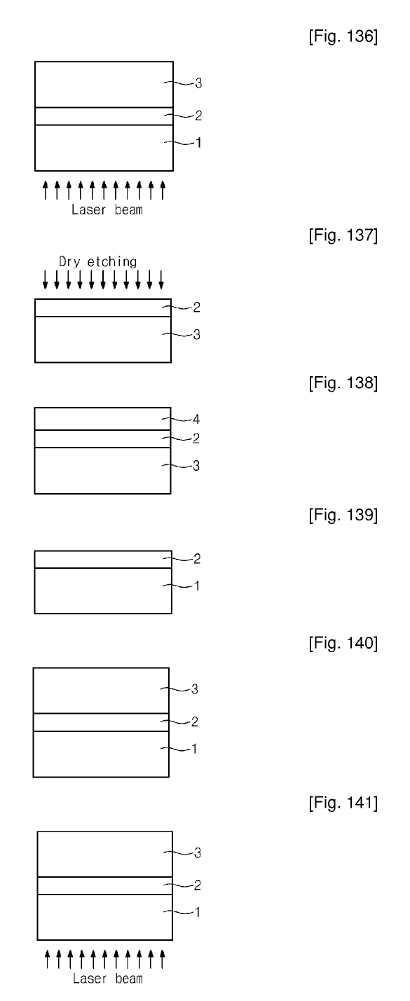

Next, as shown in FIG. 135, after sequentially growing the first epitaxial layer 1 and the thick film layer 3 on the growth substrate 1, the growth substrate 1 having inferior electrical and terminal conductivity is removed through the LLO scheme by using KrF or YAG laser beam, which is a strong energy source (see, FIG. 136).

If the laser beam having strong energy is irradiated through the rear surface of the sapphire substrate, which is the growth substrate 1, the laser beam is absorbed into the boundary surface between the first epitaxial layer and the sapphire substrate 1, so that GaN and AlN is thermally decomposed into Ga, Al and N. Thus, the sapphire substrate is removed.

Then, as shown in FIG. 136, after electrically removing the sapphire substrate 1 through the LLO scheme, the first epitaxial layer 2 is subject to the surface treatment through the wet etching and dry etching using acid or base solution to planarize the first epitaxial layer 2, before the thin film layer for the GaN-based electronic and optoelectronic devices is stacked (see, FIG. 137).

That is, before forming the stack structure of a second epitaxial layer 4 including materials expressed as chemical formula InxAlyGazN (x, y and z are integers) or SixCyNz (x, y and z are integers), in order to improve the thermal stability of the thick film layer 3 and the first epitaxial layer 2 formed on the thick film layer 3, the heat treatment process is performed for 30 seconds to 24 hours under the oxygen, nitrogen, argon, vacuum, air, hydrogen or ammonia atmosphere at the temperature of 800° C. or above.

In particular, the high-quality epitaxial substrate for the electronic and optoelectronic devices can be fabricated at high efficiency and low cost through the processes shown in FIGS. 134 to 137.

Next, as shown in FIG. 137, the GaN-based semiconductor multi-layer, that is, the second epitaxial layer 4 is grown on the GaN-based epitaxial substrate through MOCVD, HVPE, PLD, ALD or MBE (see, FIG. 138).

At this time, the second epitaxial layer 4 is prepared in the form of a multi-layer by using materials expressed as chemical formula InxAlyGazN (x, y and z are integers) or SixCyNz (x, y and z are integers).

In addition, IV-elements (Si, Ge, Te, Se), which are n-type dopant, and III-elements (Mg, Zn, Be), which are p-type dopant, can be added to the second epitaxial layer 4 according to the type of the electronic and optoelectronic devices.

FIGS. 139 to 144 are sectional views showing the procedure of forming an epitaxial stack structure on a substrate for electronic and optoelectronic devices employing GaN-based semiconductors to provide a high quality epitaxial substrate according to a fortieth-seventh embodiment of the present invention.

Referring to FIGS. 139 to 144, a first epitaxial layer 2 is grown on the sapphire substrate which is an initial growth substrate 1 (see, FIG. 139). The first epitaxial layer 2 has a multi-layered stacking structure. The first epitaxial layer 2 includes materials having a single crystalline structure, such as GaN, AlN, InN, AlGaN, InGaN, AlInN, InAlGaN, SiC, or SiCN, which is expressed as chemical formula InxAlyGazN (x, y and z are integers) or SixCyNz (x, y and z are integers). In addition, the first epitaxial layer 2 is deposited in the form of a single layer having a thickness of 30 nm or more. Preferably, the first epitaxial layer 2 is prepared in the form of a bi-layer or a multi-layer.

The first epitaxial layer 2 formed on the growth substrate 1 may have a multi-structure corresponding to InxAlyGazN (x, y and z are integers) or SixCyNz (x, y and z are integers).

IV-elements (Si, Ge, Te, Se), which are n-type dopant, and III-elements (Mg, Zn, Be), which are p-type dopant, can be added to the first epitaxial layer 2 according to the type of the electronic and optoelectronic devices.

The first epitaxial layer 2 is preferably deposited through chemical vapor deposition (CVD), such as MOCVD, HVPE or ALD (atomic level deposition), or through physical vapor deposition, such as PLD (pulsed laser deposition) using a strong energy source, or MBE (molecular beam epitaxy).

Then, as shown in FIG. 139, a thick film layer 3 having a thickness of 30 nm or more is formed on the first epitaxial layer 2 provided on the growth substrate 1 (see, FIG. 140).

The thick film layer 3 can be formed by using materials having electrical conductivity or electrical insulating property. At this time, the thick film layer 3 is formed through electrochemical deposition, such as electroplating or electroless plating representing higher deposition rate, physical and chemical vapor deposition, such as LPCVD (low pressure CVD) or PECVD (plasma enhanced CVD), sputtering, PLD, screen printing, or fusion bonding using a metal foil.

The material of the thick film layer 3 having the thickness of 30 nm or more must have superior electrical and thermal conductivity without causing oxidation and reduction reaction under hydrogen (H2) and ammonia (NH3) atmosphere and the high temperature condition of 1000° C. or more.

In detail, the thick film layer includes at least one selected from the group consisting of Si, Ge, SiGe, GaAs, GaN, AlN, AlGaN, InGaN, BN, BP, BAs, BSb, AlP, AlAs, Alsb, GaSb, InP, InAs, InSb, GaP, InP, InAs, InSb, In2S3, PbS, CdTe, CdSe, CdlxZnxTe, In2Se3, CuInSe2, Hgl-xCdxTe, Cu2S, ZnSe, ZnTe, ZnO, W, Mo, Ni, Nb, Ta, Pt, Cu, Al, Ag, Au, ZrB2, WB, MoB, MoC, WC, ZrC, Pd, Ru, Rh, Ir, Cr, Ti, Co, V, Re, Fe, Mn, RuO, IrO2, BeO, MgO, SiO2, SiN, TiN, ZrN, HfN, VN, NbN, TaN, MoN, ReN, CuI, Diamond, DLC (diamond like carbon), SiC, WC, TiW, TiC, CuW, or SiCN.

In addition, a single crystalline stack structure, a poly-crystalline stack structure, or an amorphous stack structure is prepared in the form of a single layer, a bi-layer or a tri-layer by using the material for the thick film layer 3.

As a material for the thick film layer 3 having the thickness of 30 nm or more, alloys or solid solution of the above metals can be utilized.

Next, as shown in FIG. 140, after sequentially growing the first epitaxial layer 1 and the thick film layer 3 on the growth substrate 1, the growth substrate 1 having inferior electrical and terminal conductivity is removed through the LLO scheme by using KrF or YAG laser beam, which is a strong energy source (see, FIG. 141).

If the laser beam having strong energy is irradiated through the rear surface of the sapphire substrate, which is the growth substrate 1, the laser beam is absorbed into the boundary surface between the first epitaxial layer and the sapphire substrate 1, so that GaN and AlN is thermally decomposed into Ga, Al and N. Thus, the sapphire substrate is removed.

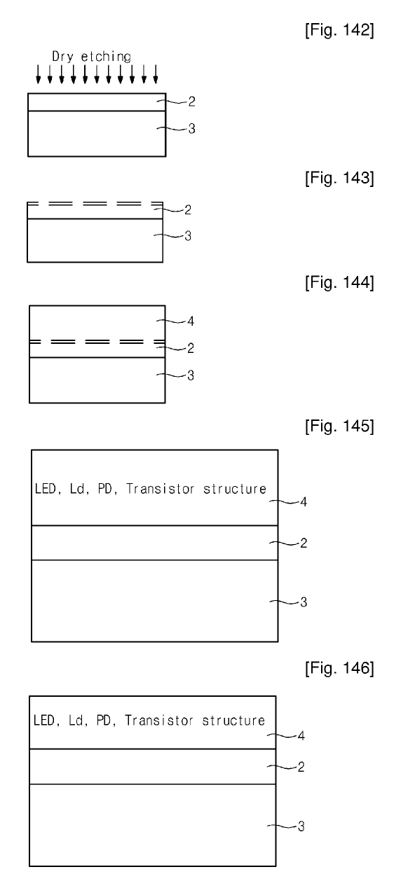

Then, as shown in FIG. 141, after electrically removing the sapphire substrate 1 through the LLO scheme, the first epitaxial layer 2 is subject to the surface treatment through the wet etching and dry etching using acid or base solution to planarize the first epitaxial layer 2, before the thin film layer for the GaN-based electronic and optoelectronic devices is stacked (see, FIG. 142).

That is, before forming the stack structure of a second epitaxial layer 4 including materials expressed as chemical formula InxAlyGazN (x, y and z are integers) or SixCyNz (x, y and z are integers), in order to improve the thermal stability of the thick film layer 3 and the first epitaxial layer 2 formed on the thick film layer 3, the heat treatment process is performed for 30 seconds to 24 hours under the oxygen, nitrogen, argon, vacuum, air, hydrogen or ammonia atmosphere at the temperature of 800° C. or above.

Then, as shown in FIG. 142, before growing the second epitaxial layer 4 is grown on the first epitaxial layer 2, which has been planarized through the surface treatment, in order to grow the high quality thin film structure including materials expressed as chemical formula InxAlyGazN (x, y and z are integers) or SixCyNz (x, y and z are integers), that is, in order to grow the second epitaxial stack structure, the patterning process, such as ELOG (epitaxial lateral overgrowth), is performed (see, FIG. 143).

Next, as shown in FIG. 143, the GaN-based semiconductor multi-layer, that is, the second epitaxial layer 4 is grown on the GaN-based epitaxial substrate through MOCVD, HVPE, PLD, ALD or MBE (see, FIG. 144).

At this time, the second epitaxial layer 4 is prepared in the form of a multi-layer by using materials expressed as chemical formula InxAlyGazN (x, y and z are integers) or SixCyNz (x, y and z are integers).

In addition, IV-elements (Si, Ge, Te, Se), which are n-type dopant, and III-elements (Mg, Zn, Be), which are p-type dopant, can be added to the second epitaxial layer 4 according to the type of the electronic and optoelectronic devices.

FIG. 145 is a sectional view showing first and second epitaxial stack structures sequentially formed on a thick film layer according to a fortieth-eighth embodiment of the present invention.

Referring to FIG. 145, the thick film layer 3 is primarily formed by using Mo, W, Si, GaN, SiC, AlN, or TiN, which is chemically and thermally stable in the hydrogen and ammonia atmosphere and at the temperature of 1000° C. or above. Then, the first epitaxial layer 2 including undoped GaN grown at the temperature of 1000° C. or above and n-type GaN doped with IV-elements, such as Si, and the second epitaxial layer 4 including GaN-based semiconductors for high performance electronic and optoelectronic devices are sequentially grown.

FIG. 146 is a sectional view showing first and second epitaxial stack structures sequentially formed on a thick film layer according to a fortieth-ninth embodiment of the present invention.

Referring to FIG. 146, the thick film layer 3 is primarily formed by using Mo, W, Si, GaN, SiC, AlN, or TiN, which is chemically and thermally stable in the hydrogen and ammonia atmosphere and at the temperature of 1000° C. or above. Then, the first epitaxial layer 2 including undoped GaN grown at the temperature of 1000° C. or above and n-type GaN doped with IV-elements, such as Si, and the second epitaxial layer 4 including GaN-based semiconductors for high performance electronic and optoelectronic devices are sequentially grown.

### INDUSTRIAL APPLICABILITY

As described above, when growing the light emitting structure including nitride-based semiconductors on the sapphire growth substrate, the first tunnel junction layer is introduced between the undoped nitride-based layer serving as a buffering layer and the n-type nitride-based cladding layer, or the second tunnel junction layer is formed on the p-type nitride-based cladding layer. In addition, the sapphire substrate is removed through the LLO scheme, thereby fabricating the nitride-based light emitting device having high brightness, large area, and high capacity.

In addition, electrical and optical characteristics of the n-type and p-type highly transparent or highly reflective nitride-based ohmic electrode layers formed on the n-type and p-type nitride-based cladding layers can be improved, so that the nitride-based light emitting device has superior current-voltage and high brightness characteristics. In addition, the surface roughness process and the photonic crystal effect are applied to upper and lower portions of the nitride-based cladding layer and the ohmic electrode layer, so that the external quantum efficiency (EQE) is improved and the nitride-based light emitting device having high brightness, large area, and high capacity can be fabricated as a next-generation white light source.

Furthermore, before the nitride-based light emitting structure including the nitride-based semiconductors is grown on the sapphire substrate, the nitride-based sacrificial layer, the nitride-based flattening layer and the supporting substrate layer are sequentially stacked on the sapphire substrate. In this state, the nitride-based light emitting structure including the nitride-based semiconductors is continuously grown on the sapphire substrate. When growing the nitride-based light emitting structure, the first tunnel junction layer is introduced between the undoped nitride-based layer serving as a buffering layer and the n-type nitride-based cladding layer, or the second tunnel junction layer is formed on the p-type nitride-based cladding layer. In addition, the sapphire substrate is removed through the LLO scheme, thereby fabricating the nitride-based light emitting device having high brightness, large area, and high capacity.

Accordingly, when the laser beam having strong energy is irradiated, the nitride-based semiconductor layer can be prevented from being thermally and mechanically deformed or decomposed. In addition, electrical and optical characteristics of the n-type and p-type highly transparent or highly reflective nitride-based ohmic electrode layers formed on the n-type and p-type nitride-based cladding layers can be improved, so that the nitride-based light emitting device has superior current-voltage and high brightness characteristics.

In addition, since the high-quality nitride-based semiconductor epitaxial layer is grown, the semiconductor device may have superior electrical, optical and thermal characteristics.

1. A semiconductor device comprising:
a growth substrate having an insulating property;
a nucleation layer formed on the growth substrate;
an undoped buffering nitride-based layer formed on the nucleation layer while serving as a buffering layer;
a first type nitride-based cladding layer formed on the undoped buffering nitride-based layer;
a multi quantum well nitride-based active layer formed on the first type nitride-based cladding layer;
a second type nitride-based cladding layer formed on the multi quantum well nitride-based active layer, the second type being different from the first type; and
a tunnel junction layer formed between the undoped buffering nitride-based layer and the first type nitride-based cladding layer or formed on the second type nitride-based cladding layer or formed both between the undoped buffering nitride-based layer and the first type nitride-based cladding layer and formed on the second type nitride-based cladding layer.

2. The semiconductor device of claim 1, wherein the growth substrate is removed by means of a laser beam, and the semiconductor device further comprises a first or a second type ohmic current spreading layer formed at an area where the growth substrate is removed, a supporting substrate formed on the second type nitride-based cladding layer for protecting, and a first or second type ohmic electrode layer formed between the second nitride-based cladding layer and the supporting substrate.

3. The semiconductor device of claim 2, wherein at least one shape of a dot, a hole, a pyramid, a nano-rod, and a nano-columnar having a size of 10 nm or less is formed on at least one surface of the first and second type nitride-based cladding layers, the first or second ohmic contact layer, the tunnel junction layer, and the first or second ohmic current spreading layer for providing a surface roughness and a photonic crystal effect.

4. The semiconductor device of claim 1, wherein the tunnel junction layer basically includes one selected from compounds expressed as AlaInbGacNxPyAsz (a, b, c, x, y and z are integers) consisting of III-V group elements, in which the tunnel junction layer is prepared in a form of a single layer or a multi-layer having a thickness of 50 nm or less.

5. The semiconductor device of claim 4, wherein the multi-layer includes a super-lattice structure in which a stack of 30 or less pairs is repeatedly stacked including InGaN/GaN, AlGaN/GaN, AlInN/GaN, AlGaN/InGaN, AlInN/InGaN, AlN/GaN, and AlGaAs/InGaAs, wherein the multi-layer includes a single crystal layer, a poly-crystal layer or an amorphous layer having III-group elements (Mg, Be, Zn) or IV-group elements (Si, Ge) added thereto.

6. The semiconductor device of claim 2, wherein the supporting substrate includes silicide that is an intermetallic compound, formed from at least one of aluminum (Al), Al-related alloy, Al solid solution, copper (Cu), Cu-related alloy, Cu solid solution, silver (Ag), Ag-related alloy, or Ag solid solution.

7. The semiconductor device of claim 2, wherein the first type or the second type ohmic contact layer includes a thick layer of Ag, Rh, Al, which is a high reflective metal, or alloys or solid solution based on the high reflective metals, a dual reflective layer or a triple reflective layer including the high reflective metal combined with nickel (Ni), palladium (Pd), platinum (Pt), zinc (Zn), magnesium (Mg), or gold (Au), or a combination of transparent conductive oxide (TCO), transitional metal-based transparent conductive nitride, and the high reflective metal.

8. The semiconductor device of claim 2, wherein the first type or the second type ohmic current spreading layer includes a transparent conductive thin film layer employing transparent conductive oxide (TCO), or transitional metal-based transparent conductive nitride (TCN).

9. The semiconductor device of claim 8, wherein the TCO is compound including oxygen (O) combined with at least one selected from the group consisting of indium (In), tin (Sn), zinc (Zn), gallium (Ga), cadmium (Cd), magnesium (Mg), beryllium (Be), silver (Ag), molybdenum (Mo), vanadium (V), copper (Cu), iridium (Ir), rhodium (Rh), ruthenium (Ru), tungsten (W), titanium (Ti), tantalum (Ta), cobalt (Co), nickel (Ni), manganese (Mn), platinum (Pt), palladium (Pd), aluminum (Al), and lanthanoid (La), and the TCN is transparent conductive compound obtained by combining nitrogen (N) with titanium (Ti), tungsten (W), tantalum (Ta), vanadium (V), chrome (Cr), zirconium (Zr), niobium (Nb), hafnium (Hf), rhenium (Re) or molybdenum (Mo).

10. The semiconductor device of claim 8, wherein the first type or the second type ohmic current spreading layer include metal components that form a new transparent conductive thin film in combination with the first-type or the second type nitride-based cladding layers when it is subject to the heat treatment process at a nitrogen atmosphere or an oxygen atmosphere.

11. The semiconductor device of claim 2, wherein the first type or the second type ohmic current spreading layer is formed through sputtering deposition using oxygen, nitrogen, argon or hydrogen plasma and pulsed laser deposition using strong laser beam as an energy source.

12. The semiconductor device of claim 2, wherein, in order to form the first type or the second type ohmic electrode layer and apply surface roughness and photonic crystal effect to a surface of the first type or the second type ohmic electrode layer, a heat treatment process is performed for 10 seconds to 3 hours under at least one condition of nitrogen (N₂), argon (Ar), helium (He), oxygen (O₂), air and vacuum atmospheres at the temperature in a range of a normal temperature to 800° C.

13. The semiconductor device of claim 1, wherein one of the first and second types is an n type and the other is a p type.

14. A semiconductor device comprising:
a growth substrate having an insulating property;
a nitride-based semiconductor thin film layer formed on the growth substrate;
a supporting substrate layer formed on the nitride-based semiconductor thin film layer; and
a light emitting structure formed on the supporting substrate layer.

15. The semiconductor device of claim 14, wherein the nitride-based semiconductor thin film layer includes a nitride-based sacrificial layer consisting of III-group nitride-based semiconductors, or the nitride-based sacrificial layer and a nitride-based flattening layer formed on the nitride-based sacrificial layer.

16. The semiconductor device of claim 14, wherein the supporting substrate layer includes an AlN material layer prepared as a single layer or a multi-layer.

17. The semiconductor device of claim 14, wherein the supporting substrate layer includes metal, nitride, oxide, boride, carbide, silicide, oxy-nitride, and carbon nitride material layer prepared as a single layer or a multi-layer.

18. The semiconductor device of claim 17, wherein the metal is selected from the group consisting of Ta, Ti, Zr, Cr, Sc, Si, Ge, W, Mo, Nb, and Al, the nitride is selected from the group consisting of Ti, V, Cr, Be, B, Hf, Mo, Nb, V, Zr, Nb, Ta, Hf, Al, B, Si, In, Ga, Sc, W, and rare-earth metal-based nitride, the oxide is selected from the group consisting of Ti, Ta, Li, Al, Ga, In, Be, Nb, Zn, Zr, Y, W, V, Mg, Si, Cr, La and rare-earth metal-based oxide, the boride is selected from the group consisting of Ti, Ta, Li, Al, Be, Mo, Hf, W, Ga, In, Zn, Zr, V, Y, Mg, Si, Cr, La and rare-earth metal-based boride, the carbide is selected from the group consisting of Ti, Ta, Li, B, Hf, Mo, Nb, W, V, Al, Ga, In, Zn, Zr, Y, Mg, Si, Cr, La and rare-earth metal-based carbide, the silicide is selected from the group consisting of Cr, Hf, Mo, Nb, Ta, Th, Ti, W, V, Zr and rare-earth metal-based silicide, the oxy-nitride includes Al—O—N and the carbon nitride includes Si—C—N.

19. The semiconductor device of claim 14, wherein the supporting substrate layer is prepared in a form of a single layer, or a multi-layer including an AlaObNc (a, b and c are integers) and a GaxOy-based material layer (x and y are integers).

20. The semiconductor device of claim 14, wherein the supporting substrate layer is prepared in a form of a single layer, or a multi-layer including SiaAlbNcCd-based material (a, b, c and d are integers).

21. The semiconductor device of claim 16 wherein the supporting substrate layer includes a single crystal material layer having a hexagonal system or a cubic system, a poly-crystal material layer or an amorphous material layer.

22. The semiconductor device of claim 21, wherein the supporting substrate layer has a thickness of 10 μm or less and represents a reduction-resistant characteristic and thermal and chemical stability at a temperature of 1000° C. or more and in a hydrogen gas or ion atmosphere.

23. The semiconductor device of claim 14, wherein the light emitting structure comprises:
a nucleation layer formed on the supporting substrate layer;
an undoped buffering nitride-based layer formed on the nucleation layer while serving as a buffering layer;
a first type nitride-based cladding layer formed on the undoped buffering nitride-based layer;
a multi quantum well nitride-based active layer formed on the first type nitride-based cladding layer; and
a second type nitride-based cladding layer formed on the multi quantum well nitride-based active layer, the second type being different from the first type.

24. The semiconductor device of claim 23, further comprising a tunnel junction layer formed between the undoped buffering nitride-based layer and the first type nitride-based cladding layer or formed on the second type nitride-based cladding layer or formed both between the undoped buffering nitride-based layer and the first type nitride-based cladding layer and formed on the second type nitride-based cladding layer.

25. The semiconductor device of claim 24, wherein the tunnel junction layer basically includes one selected from compounds expressed as AlalnbGacNxPyAsz (a, b, c, x, y and z are integers) consisting of III-V group elements, in which the tunnel junction layer is prepared in a form of a single layer or a multi-layer having a thickness of 50 nm or less.

26. The semiconductor device of claim 25, wherein the multi-layer includes a super-lattice structure in which a stack structure of 30 or less pairs is repeatedly stacked including InGaN/GaN, AlGaN/GaN, AlInN/GaN, AlGaN/InGaN, AlInN/InGaN, AlN/GaN, and AlGaAs/InGaAs, wherein the multi-layer includes a single crystal layer, a poly-crystal layer or an amorphous layer having II-group elements (Mg, Be, Zn) or IV-group elements (Si, Ge) added thereto.

27. The semiconductor device of claim 24, further comprising:
a first or a second type ohmic current spreading layer formed on the light emitting structure where the growth substrate is removed by means of the laser beam; and
a first or second type ohmic electrode layer formed at a lower portion of the light emitting structure.

28. The semiconductor device of claim 27, further comprising a heat sink thin layer formed at a lower portion of the first or the second type ohmic current spreading layer.

29. The semiconductor device of claim 28, wherein the heat sink thin layer is formed through an electroplating process or a bonding transfer process, and the semiconductor device further comprises a bonding layer interposed between the first or the second ohmic electrode layer and the heat sink thin layer during the bonding transfer process.

30. The semiconductor device of claim 28, wherein the heat sink thin layer emitting heat includes at least one selected from the group consisting of silicon having silicide that is an intermetallic compound, aluminum (Al), Al-related alloy and solid solution, copper (Cu), Cu-related alloy and solid solution, silver (Ag), and Ag-related alloy and solid solution.

31. The semiconductor device of claim 27, wherein a dot, a hole, a pyramid, a nano-rod, or a nano-columnar having a size of 10 nm or less is formed on at least one surface of the first and second type nitride-based cladding layers, the first or second ohmic contact layer, the tunnel junction layer, and the first or second ohmic current spreading layer for providing a surface roughness and a photonic crystal effect.

32. The semiconductor device of claim 27, wherein the first type or the second type ohmic contact layer includes a thick layer of Ag, Rh, Al which is a high reflective metal, alloys or solid solution based on the high reflective metals, a dual reflective layer or a triple reflective layer including the high reflective metal combined with nickel (Ni), palladium (Pd), platinum (Pt), zinc (Zn), magnesium (Mg), or gold (Au), or a combination of transparent conductive oxide (TCO), transitional metal-based transparent conductive nitride, and the high reflective metal.

33. The semiconductor device of claim 27, wherein the first type or the second type ohmic current spreading layer includes a transparent conductive thin film layer employing transparent conductive oxide (TCO), or transitional metal-based transparent conductive nitride (TCN).

34. The semiconductor device of claim 33, wherein the TCO is compound including oxygen (O) combined with at least one selected from the group consisting of indium (In), tin (Sn), zinc (Zn), gallium (Ga), cadmium (Cd), magnesium (Mg), beryllium (Be), silver (Ag), molybdenum (Mo), vanadium (V), copper (Cu), iridium (Ir), rhodium (Rh), ruthenium (Ru), tungsten (W), titanium (Ti), tantalum (Ta), cobalt (Co), nickel (Ni), manganese (Mn), platinum (Pt), palladium (Pd), aluminum (Al), and lanthanoid (La), and the TCN is transparent conductive compound obtained by combining nitrogen (N) with titanium (Ti), tungsten (W), tantalum (Ta), vanadium (V), chrome (Cr), zirconium (Zr), niobium (Nb), hafnium (Hf), rhenium (Re) or molybdenum (Mo).

35. The semiconductor device of claim 34, wherein the first type or the second type ohmic current spreading layer include metal components that form a new transparent conductive thin film in combination with the first-type or the second type nitride-based cladding layers when it is subject to the heat treatment process at a nitrogen atmosphere or an oxygen atmosphere.

36. The semiconductor device of claim 27, wherein the first type or the second type ohmic current spreading layer is formed through sputtering deposition using oxygen, nitrogen, argon or hydrogen plasma and pulsed laser deposition using strong laser beam as an energy source.

37. The semiconductor device of claim 27, wherein, in order to form the first type or the second type ohmic electrode layer and apply surface roughness and photonic crystal effect to a surface of the first type or the second type ohmic electrode layer, a heat treatment process is performed for 10 seconds to 3 hours under at least one condition of nitrogen (N₂), argon (Ar), helium (He), oxygen (O₂), air and vacuum atmospheres at the temperature in a range of a normal temperature to 800° C.

38. The semiconductor device of claim 23, wherein one of the first and second types is an n type and the other is a p type.

39. A semiconductor device comprising:
a thick film layer;
a first epitaxial layer formed on the thick film layer, in which a top surface of the first epitaxial layer is surface-treated; and
a second epitaxial layer formed on the first epitaxial layer and having a multi-layer including nitride-based semiconductors for electronic and optoelectronic devices, wherein each of the first and second epitaxial layer is prepared in a form of a single layer or a multi-layer including at least one compound expressed as InxAlyGazN (x, y and z are integers) or SixCyNz (x, y and z are integers).

40. The semiconductor device of claim 39, wherein the thick film layer includes at least one compound, an alloy or solid solution selected from the group consisting of Si, Ge, SiGe, GaAs, GaN, AlN, AlGaN, InGaN, BN, BP, BAs, BSb, AlP, AlAs, Alsb, GaSb, InP, InAs, InSb, GaP, InP, InAs, InSb, In2S3, PbS, CdTe, CdSe, CdlxZnxTe, In2Se3, CuInSe2, Hgl-xCdxTe, Cu2S, ZnSe, ZnTe, ZnO, W, Mo, Ni, Nb, Ta, Pt, Cu, Al, Ag, Au, ZrB2, WB, MoB, MoC, WC, ZrC, Pd, Ru, Rh, Ir, Cr, Ti, Co, V, Re, Fe, Mn, RuO, IrO2, BeO, MgO, SiO2, SiN, TiN, ZrN, HfN, VN, NbN, TaN, MoN, ReN, CuI, Diamond, DLC (diamond like carbon), SiC, WC, TiW, TiC, CuW, and SiCN, in which the thick film layer includes a single crystalline layer, a poly-crystalline layer or an amorphous layer prepared as a single layer or a multi-layer.

41. A method for manufacturing a semiconductor device comprising the steps of:
forming a first epitaxial layer on a growth substrate having an insulating property;
depositing a thick film layer having a thickness of 30 or more on the first epitaxial layer;
removing the growth substrate by using a laser beam; and
treating a surface of the first epitaxial layer, which is exposed as the growth substrate is removed.

42. The method of claim 41, wherein the first epitaxial layer includes at least one compound expressed as InxAlyGazN (x, y and z are integers) or SixCyNz (x, y and z are integers), and is prepared as a single layer or a multi-layer having a thickness of at least 30 nm.

43. The method of claim 42, wherein the compound includes at least one of GaN, AlN, InN, AlGaN, InGaN, AlInN, InAlGaN, SiC, and SiCN.

44. The method of claim 42, wherein the first epitaxial layer includes IV-elements (Si, Ge, Te, Se), which are n-type dopants, or III-elements (Mg, Zn, Be), which are p-type dopants.

45. The method of claim 41, wherein the thick film layer includes at least one compound, an alloy or solid solution selected from the group consisting of Si, Ge, SiGe, GaAs, GaN, AlN, AlGaN, InGaN, BN, BP, BAs, BSb, AlP, AlAs, Alsb, GaSb, InP, InAs, InSb, GaP, InP, InAs, InSb, In2S3, PbS, CdTe, CdSe, Cdl-xZnxTe, In2Se3, CuInSe2, Hgl-xCdxTe, Cu2S, ZnSe, ZnTe, ZnO, W, Mo, Ni, Nb, Ta, Pt, Cu, Al, Ag, Au, ZrB2, WB, MoB, MoC, WC, ZrC, Pd, Ru, Rh, Ir, Cr, Ti, Co, V, Re, Fe, Mn, RuO, IrO2, BeO, MgO, SiO2, SiN, TiN, ZrN, HfN, VN, NbN, TaN, MoN, ReN, Cul, Diamond, DLC (diamond like carbon), SiC, WC, TiW, TiC, CuW, and SiCN, in which the thick film layer includes a single crystalline layer, a poly-crystalline layer or an amorphous layer prepared as a single layer or a multi-layer.

46. The method of claim 41, wherein the removing the growth substrate using the laser beam includes at least one of an etching process, a surface treatment process and a heat treatment process.

47. The method of claim 41, wherein the treating a surface of the first epitaxial layer includes at least one of a surface flattening process, a patterning process, and a heat treatment process.

48. The method of claim 41, further comprising forming a second epitaxial layer on a surface-treated surface of the first epitaxial layer.

49. The method of claim 48, wherein the second epitaxial layer includes a multi-layer including GaN-based semiconductors for electronic and optoelectronic devices.

50. The method of claim 48, wherein the second epitaxial layer includes a single crystalline multi-layer including at least one compound expressed as InxAlyGazN (x, y and z are integers) or SixCyNz (x, y and z are integers).

51. The method of claim 50, wherein the second epitaxial layer includes IV-elements (Si, Ge, Te, Se), which are n-type dopants, or III-elements (Mg, Zn, Be), which are p-type dopants.

52. The method of claim 48, wherein the second epitaxial layer is formed by performing a heat treatment process for 30 seconds to 24 hours at a temperature of 200° C. under an oxygen, nitrogen, vacuum, air, hydrogen or ammonia atmosphere.
